(19) United States
(12) Patent Application Publication
(10) Pub. No.: US 2024/0081008 A1
(43) Pub. Date: Mar. 7, 2024

(54) DISPLAY DEVICE

(71) Applicants: Samsung Display Co., Ltd., Yongin-si (KR); AUFLEX Co., Ltd., Hwaseong-si (KR)

(72) Inventors: SEYONG KIM, Yongin-si (KR); Myoung Ho LIM, Ansan-si (KR); Seoung Jun LEE, Uiwang-si (KR)

(73) Assignees: Samsung Display Co., Ltd., Yongin-si (KR); AUFLEX Co., Ltd., Hwaseong-si (KR)

(21) Appl. No.: 18/348,694

(22) Filed: Jul. 7, 2023

(30) Foreign Application Priority Data
Sep. 2, 2022 (KR) 10-2022-0111652

(51) Int. Cl. H05K 5/02

(52) U.S. Cl. CPC H05K 5/0226

(57) ABSTRACT

A display device which includes a display assembly including a first non-folding region and a second non-folding region disposed in a first direction and a folding region disposed between the first and second non-folding regions, a first body disposed under the first non-folding region, a second body disposed under the second non-folding region, a hinge assembly that is disposed between the first body and the second body and defining biaxial rotational axes extending parallel to a second direction intersecting the first direction, a first bracket and a second bracket disposed on opposite sides of the hinge assembly opposite each other in the second direction, the first bracket and the second bracket being disposed in the first direction and adjacent to the biaxial rotational axes, and a plurality of protrusions that are connected to the opposite sides of the hinge assembly and protruding between the first bracket and the second bracket.

### CROSS-REFERENCE TO RELATED APPLICATION(S)

This application claims priority to and benefits of Korean Patent Application No. 10-2022-0111652 under 35 U.S.C. § 119, filed on Sep. 2, 2022 in the Korean Intellectual Property Office, the entire contents of which are incorporated herein by reference.

### BACKGROUND

### 1. Technical Field

Embodiments of the disclosure relate to a display device.

### 2. Description of the Related Art

Electronic devices, such as a smart phone, a digital camera, a notebook computer, a car navigation device, a smart television, and the like, which provide an image to a user include a display device for displaying an image. The display device may generate an image and provide the image to the user through a display screen.

Recently, with the development of display device technology, various forms of display devices have been developed. For example, various display devices that can be curved, folded, or rolled have been developed. Such display devices may be easy to carry and may improve user convenience.

Among flexible display devices, a foldable display device may include a display module or assembly that is folded about a folding axis extending in a direction. The display module may be folded or unfolded about the folding axis. The display module may include a folding region that is bent in a folding operation. A hinge module or assembly that supports the folding region and has a low risk of damage due to impact is required.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments of the disclosure provide a display device including protrusions and brackets for preventing damage to a hinge module or assembly in case that a drop impact force is applied to the hinge assembly.

According to an embodiment, a display device may include a display assembly including a first non-folding region and a second non-folding region that are disposed in a first direction and a folding region disposed between the first and second non-folding regions, a first body disposed under the first non-folding region, a second body disposed under the second non-folding region, a hinge assembly disposed between the first body and the second body and defining biaxial rotational axes extending parallel to a second direction intersecting the first direction, a first bracket and a second bracket that are disposed on opposite sides of the hinge assembly opposite each other in the second direction, the first bracket and the second bracket being disposed in the first direction and adjacent to the biaxial rotational axes, and a plurality of protrusions connected to the opposite sides of the hinge assembly and protruding between the first bracket and the second bracket.

In case that the display assembly is unfolded, the protrusions may make physical contact with a side of the first bracket and a side of the second bracket facing each other in the first direction.

The protrusions may be disposed between the biaxial rotational axes when viewed in the second direction.

In case that the display assembly is folded, the first and second bodies may rotate about the biaxial rotational axes and face each other. The protrusions may make physical contact with the side of the first bracket and the side of the second bracket in a third direction intersecting a plane defined by the first and second directions.

The protrusions may be fixed without being rotated. The side of the first bracket and the side of the second bracket may move along outer surfaces of the protrusions when viewed in the second direction.

The protrusions may be supported by the first and second brackets and may limit movement of the hinge assembly.

The hinge assembly may include first hinge parts spaced apart from each other in the second direction and defining the opposite sides of the hinge assembly. The first bracket and the second bracket may be connected to a corresponding first hinge part among the first hinge parts.

The first bracket and the second bracket may be connected to the outside of the corresponding first hinge part among the outsides of the first hinge parts not facing each other in the second direction and rotate about the biaxial rotational axes.

Each of the first hinge parts may include a main frame, a plurality of sub-frames connected to opposite sides of the main frame opposite each other in the second direction, and a plurality of first gear parts overlapping the biaxial rotational axes and rotate about the biaxial rotational axes in opposite directions. The protrusions may protrude from a side of the main frame facing toward the outside of the hinge assembly in the second direction, and the first gear parts may be connected to an opposite side of the main frame opposite the side of the main frame in the second direction

The sub-frames may be coupled to the first gear parts. In case that the first gear parts rotate, the sub-frames may rotate together with the first gear parts.

The first bracket and the second bracket may be connected to the sub-frames of the corresponding first hinge part. In case that the first gear parts rotate, the first bracket and the second bracket may rotate about the biaxial rotational axes.

Each of the first hinge parts may further include a plurality of second gear parts disposed between the first gear parts and engaged with the first gear parts to rotate together with the first gear parts, and a plurality of coupling pieces connecting the sub-frames to the main frame.

The sub-frames may be disposed in sliding grooves defined on surfaces of the coupling pieces facing toward the outside of the hinge assembly. The sliding grooves may have a curved shape, and in case that the first gear parts rotate, the sub-frames may move along a curved path defined by the sliding grooves.

The display device may further include a plurality of wing plates disposed on the first body and the second body and connected to opposite sides of the first hinge parts opposite each other in the first direction.

Each of the wing plates may include a first wing plate, and a second wing plate closer to the centers of the first hinge parts than the first wing plate, the second wing plate being rotatably coupled to the first wing plate. The second wing plate may be connected to a side of the first wing plate facing the second wing plate.

The first and second wing plates of the wing plates may be coupled to the sub-frames and rotate together with the sub-frames.

The first wing plates of the wing plates may be coupled to the first gear parts and rotate together with the first gear parts.

The folding region may include a curved portion bent in a curved shape, and reverse curvature portions disposed between the first non-folding region and the curved portion and between the second non-folding region and the curved portion and bent so as to be symmetrical to each other, the reverse curvature portions being bent opposite to the curved portion.

According to an embodiment, a display device may include a display assembly including a first non-folding region, a folding region, and a second non-folding region disposed in a first direction, a first body disposed under the first non-folding region, a second body disposed under the second non-folding region, a hinge assembly disposed between the first body and the second body and defining biaxial rotational axes extending parallel to a second direction intersecting the first direction, and a plurality of protrusions connected to opposite sides of the hinge assembly opposite each other in the second direction and protruding outside the hinge assembly.

According to an embodiment, a display device may include a display assembly including a first non-folding region and a second non-folding region disposed in a first direction and a folding region disposed between the first and second non-folding regions, a first body disposed under the first non-folding region, a second body disposed under the second non-folding region, a hinge assembly disposed between the first body and the second body and defining biaxial rotational axes extending parallel to a second direction intersecting the first direction, a first bracket and a second bracket that are disposed on opposite sides of the hinge assembly opposite each other in the second direction, the first bracket and the second bracket being disposed in the first direction and adjacent to the biaxial rotational axes, and a plurality of protrusions protruding between the first bracket and the second bracket from opposite sides of the hinge assembly and that physically contact a side of the first bracket and a side of the second bracket facing each other.

### BRIEF DESCRIPTION OF THE DRAWINGS

The above and other objects and features of the disclosure will become apparent by describing in detail embodiments thereof with reference to the accompanying drawings.

FIG. 1 is a schematic perspective view of a display device according to an embodiment of the disclosure.

FIG. 2 is a schematic view illustrating a folded state of the display device illustrated in FIG. 1.

FIG. 3 is an exploded schematic perspective view of the display device illustrated in FIG. 1.

FIG. 4 is a schematic view illustrating a section of a display module illustrated in FIG. 3.

FIG. 5 is a schematic view illustrating a section of a display panel illustrated in FIG. 4.

FIG. 6 is a schematic plan view of the display panel illustrated in FIG. 5.

FIG. 7 is a schematic block diagram of the display device illustrated in FIG. 3.

FIG. 8 is a more detailed schematic plan view of the display device illustrated in FIG. 1.

FIG. 9 is an exploded schematic perspective view of the display device illustrated in FIG. 8.

FIG. 10 is a schematic plan view of a folding set illustrated in FIG. 9.

FIG. 11 is an exploded schematic perspective view of the folding set illustrated in FIG. 10.

FIG. 12 is an exploded schematic perspective view of a hinge module illustrated in FIG. 11.

FIGS. 13A to 13E are detailed schematic views illustrating a configuration of wing plates illustrated in FIG. 11.

FIGS. 14A to 14C are schematic views illustrating detailed components of a first hinge part.

FIG. 15 is a schematic perspective view of a second connecting part illustrated in FIGS. 14A and 14B.

FIG. 16 is a schematic perspective view of a bracket of FIG. 12.

FIG. 17 is an enlarged schematic perspective view of brackets coupled to a first hinge unit.

FIG. 18 is an exploded schematic perspective view of a second hinge part.

FIGS. 19A to 19C are schematic views illustrating the first hinge part and the brackets of FIG. 12.

FIG. 20A is a schematic sectional view taken along line II-II′ of FIG. 19A.

FIGS. 20B and 20C are schematic views for describing a folded state of the folding set and the display module illustrated in FIG. 20A.

### DETAILED DESCRIPTION OF THE EMBODIMENTS

The above and other aspects, features, and advantages of the disclosure will become apparent from the following description of embodiments given in conjunction with the accompanying drawings. However, the disclosure is not limited to the embodiments disclosed herein and may be implemented in various different forms. Like reference numerals refer to like elements throughout.

When one element or layer is referred to as being “on” another element or layer, it can be directly on the other element or layer, or intervening elements or layers may be present. In contrast, when one element is referred to as being “directly on” another element or layer, there may be no intervening elements or layers present.

As used herein, the term “and/or” includes each of mentioned items and all combinations of one or more of the items. For example, “A and/or B” may be understood to mean any combination including “A, B, or A and B.” The terms “and” and “or” may be used in the conjunctive or disjunctive sense and may be understood to be equivalent to “and/or.”

Spatially relative terms, such as “below”, “beneath”, “lower”, “above”, “upper” and the like, may be used to describe a correlation between one element or component and another element or component as illustrated in the drawings. The spatially relative terms should be understood as terms including different directions of an element during use or operation in addition to the direction illustrated in the drawings.

Although the terms “first,” “second,” and the like are used herein to describe various elements, components, and/or sections, these elements, components, and/or sections should not be limited by these terms. These terms are only used to distinguish one element, component, or section from another element, component, or section. Accordingly, a first element, a first component, or a first section mentioned below could be termed a second element, a second component, or a second section within the spirit and scope of the disclosure.

Embodiments described herein will be described with reference to plan views and sectional views which are ideal schematic views of the disclosure. Accordingly, the forms of illustrative drawings may be changed according to manufacturing technology and/or allowable errors. Embodiments of the disclosure are not limited to specific forms illustrated, but include changes in the forms generated according to manufacturing processes. Regions illustrated in the drawings have schematic properties, and the shapes of the regions illustrated in the drawings illustrate specific forms of regions of devices and are not intended to limit the scope of the disclosure.

It will be understood that the terms “connected to” or “coupled to” may include a physical or electrical connection or coupling.

The terms “face” and “facing” mean that a first element may directly or indirectly oppose a second element. In a case in which a third element intervenes between the first and second element, the first and second element may be understood as being indirectly opposed to one another, although still facing each other.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

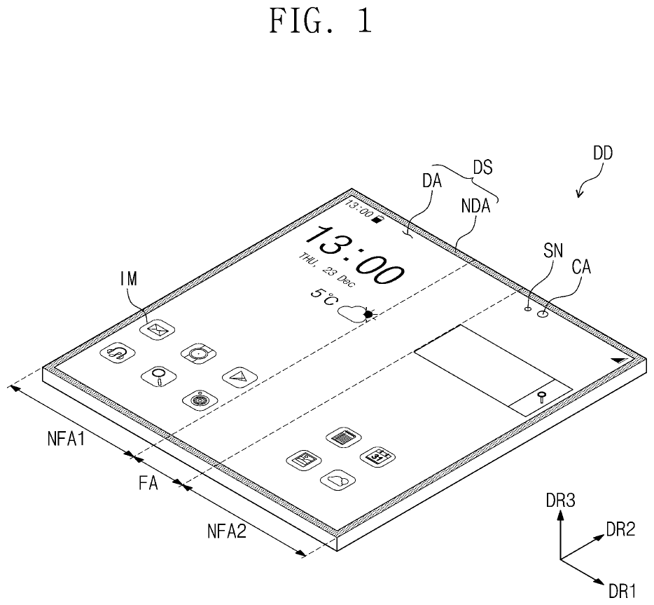

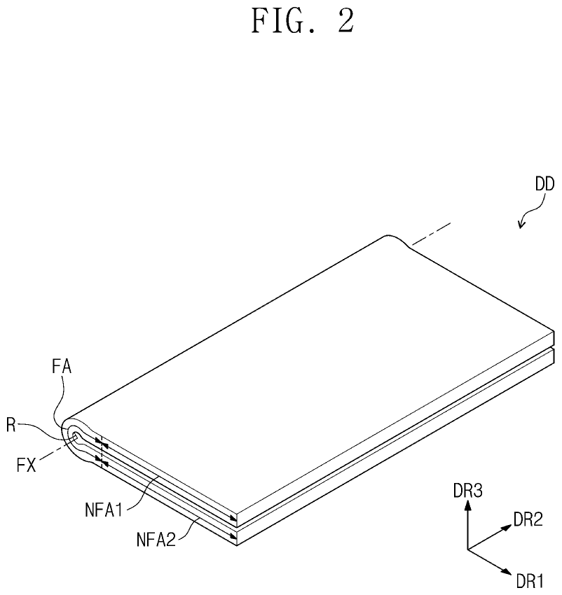

FIG. 1 is a schematic perspective view of a display device according to an embodiment of the disclosure. FIG. 2 is a schematic view illustrating a folded state of the display device illustrated in FIG. 1.

Referring to FIG. 1, the display device DD according to an embodiment of the disclosure may have a rectangular shape with short sides extending in a first direction DR1 and long sides extending in a second direction DR2 crossing or intersecting the first direction DR1. However, without being limited thereto, the display device DD may have various shapes such as a circular shape, a polygonal shape, and the like. The display device DD may be a flexible display device.

Hereinafter, a direction substantially perpendicular to a plane defined by the first direction DR1 and the second direction DR2 may be defined as a third direction DR3. Furthermore, the expression “plan view” used herein may mean that a device is viewed in the third direction DR3.

The display device DD may include a folding region FA and non-folding regions NFA1 and NFA2. The non-folding regions NFA1 and NFA2 may include the first non-folding region NFA1 and the second non-folding region NFA2. The folding region FA may be disposed between the first non-folding region NFA1 and the second non-folding region NFA2. The first non-folding region NFA1, the folding region FA, and the second non-folding region NFA2 may be arranged or disposed in the first direction DR1.

Although one folding region FA and two non-folding regions NFA1 and NFA2 are illustrated as an example, the number of folding regions FA and the number of non-folding regions NFA1 and NFA2 are not limited thereto. For example, the display device DD may include more than two non-folding regions and folding regions disposed between the non-folding regions.

An upper surface of the display device DD may be defined as a display surface DS, and the display surface DS may have a plane defined by the first direction DR1 and the second direction DR2. Images IM generated by the display device DD may be provided to a user through the display surface DS.

The display surface DS may include a display region DA and a non-display region NDA around the display region DA. The display region DA may display an image, and the non-display region NDA may not display an image. The non-display region NDA may surround the display region DA and may define a border of the display device DD that is printed in a predetermined or selected color.

The display device DD may include at least one sensor SN and at least one camera CA. The sensor SN and the camera CA may be adjacent to the border of the display device DD. The sensor SN and the camera CA may be disposed in the display region DA adjacent to the non-display region NDA. The sensor SN and the camera CA may be disposed in the second non-folding region NFA2. However, without being limited thereto, the sensor SN and the camera CA may be disposed in the first non-folding region NFA1.

Light may transmit through the portions of the display device DD where the sensor SN and the camera CA are disposed and may be provided to the camera CA and the sensor SN. For example, the sensor SN may be a proximity illuminance sensor. However, the type of the sensor SN is not limited thereto. The camera CA may take an external image. Multiple sensors SN and/or multiple cameras CA may be provided.

Referring to FIG. 2, the display device DD may be a foldable display device DD that is folded or unfolded. For example, the folding region FA may be bent about a folding axis FX parallel to the second direction DR2, and thus the display device DD may be folded. The folding axis FX may be defined as a long axis parallel to the long sides of the display device DD.

The display device DD may be folded inward such that the first non-folding region NFA1 and the second non-folding region NFA2 face each other and the display surface DS is not exposed to the outside. However, embodiments of the disclosure are not limited thereto. For example, the display device DD may be folded outward about the folding axis FX such that the display surface DS is exposed to the outside.

Hereinafter, the folding axis FX may be defined as biaxial rotational axes RX1 and RX2.

The distance between the first non-folding region NFA1 and the second non-folding region NFA2 may be smaller than the radius of curvature R of the folding region FA. The folding region FA may be folded in a dumbbell shape.

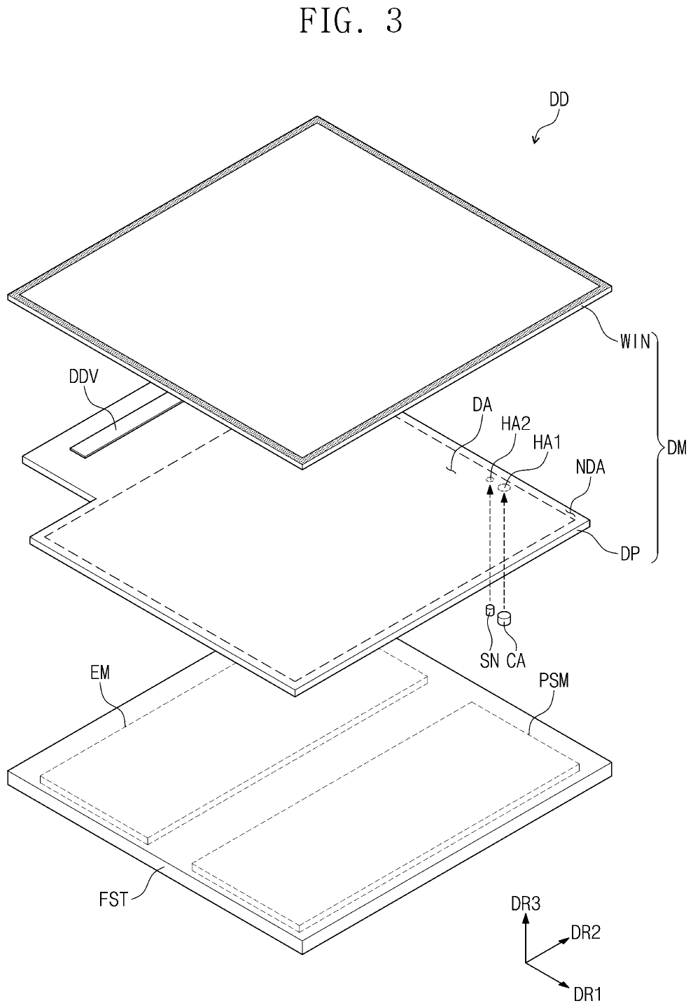

FIG. 3 is an exploded schematic perspective view of the display device illustrated in FIG. 1.

Referring to FIG. 3, the display device DD may include a display module or assembly DM, the camera CA, the sensor SN, an electronic module EM, a power supply module PSM, and a folding set FST.

The display module DM may generate an image and may detect an external input. The display module DM may include a display panel DP and a window WIN disposed on the display panel DP. The window WIN on the display panel DP may protect the display panel DP. The window WIN may transmit light generated from the display panel DP and may provide the light to the user.

The display panel DP may include a display region DA and a non-display region NDA that correspond to the display region DA (refer to FIG. 1) and the non-display region NDA (refer to FIG. 1) of the display device DD. The expression “a region/portion corresponds to another region/portion” used herein may mean that the regions/portions overlap each other and is not limited to having the same area.

The display panel DP may have a first hole region HA1 and a second hole region HA2 defined therein. The first hole region HA1 and the second hole region HA2 may have a higher light transmittance than the surrounding region. The camera CA may be disposed under the first hole region HAL and the sensor SN may be disposed under the second hole region HA2. Light passing through the first and second hole regions HA1 and HA2 may be provided to the camera CA and the sensor SN.

The display module DM may include a data driver DDV disposed on the non-display region NDA of the display panel DP. The data driver DDV may be manufactured in the form of an integrated circuit chip and may be mounted on the non-display region NDA. However, without being limited thereto, the data driver DDV may be mounted on a flexible circuit board connected to the display panel DP.

The folding set FST may be disposed under the display module DM. The folding set FST may accommodate the display module DM and may fold the display module DM. A structure of the folding set FST will be described below in detail.

The electronic module EM and the power supply module PSM may be accommodated in the folding set FST. The electronic module EM may control operations of the display device DD. The power supply module PSM may supply power to the electronic module EM.

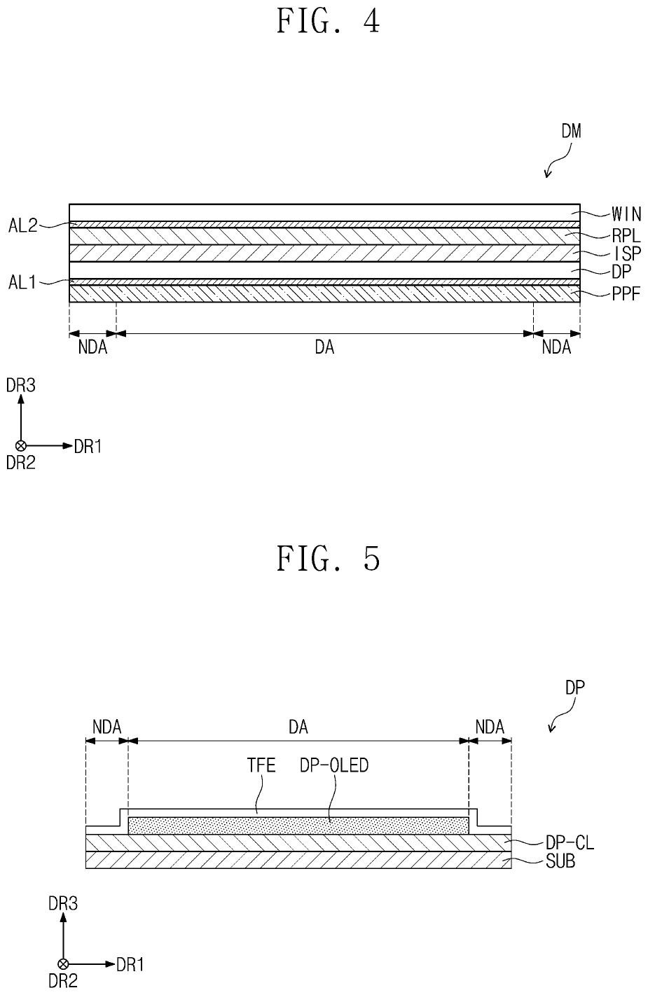

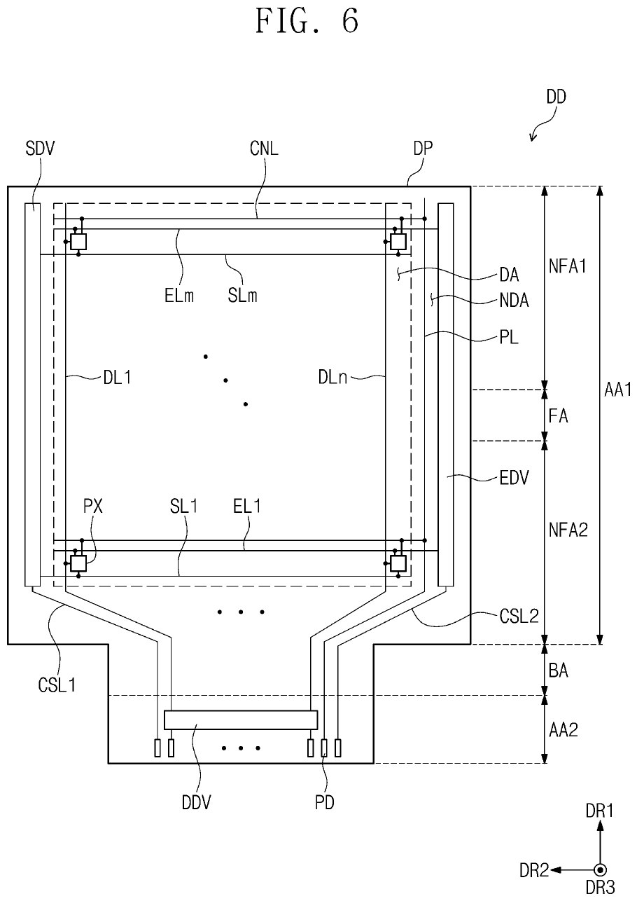

FIG. 4 is a schematic view illustrating a section of the display module illustrated in FIG. 3. FIG. 5 is a schematic view illustrating a section of the display panel illustrated in FIG. 4.

Referring to FIG. 4, the display device DD may include the display panel DP, an input sensing part ISP, an anti-reflection layer RPL, the window WIN, a panel protection film PPF, and first and second adhesive layers AL1 and AL2.

The display panel DP may be a flexible display panel. The display panel DP according to an embodiment of the disclosure may be an emissive display panel, but is not particularly limited. For example, the display panel DP may be an organic light emitting display panel or an inorganic light emitting display panel. An emissive layer of the organic light emitting display panel may include an organic light emitting material. An emissive layer of the inorganic light emitting display panel may include quantum dots, quantum rods, and/or the like. Hereinafter, an example where the display panel DP is an organic light emitting display panel will be discussed.

The input sensing part ISP may be disposed on the display panel DP. The input sensing part ISP may include multiple sensing parts (not illustrated) for sensing an external input in a capacitive manner. The input sensing part ISP may be directly manufactured on the display panel DP upon manufacturing the display device DD. However, without being limited thereto, the input sensing part ISP may be manufactured as a panel separate from the display panel DP and may be attached to the display panel DP by an adhesive layer.

The anti-reflection layer RPL may be disposed on the input sensing part ISP. The anti-reflection layer RPL may be directly manufactured on the input sensing part ISP in manufacturing the display device DD. However, without being limited thereto, the anti-reflection layer RPL may be manufactured as a separate panel and may be attached to the input sensing part ISP by an adhesive layer.

The anti-reflection layer RPL may be defined as a film for preventing reflection of external light. The anti-reflection layer RPL may decrease the reflectivity of external light incident toward the display panel DP from above the display device DD.

In case that external light travelling toward the display panel DP is reflected from the display panel DP and provided back to the user, the user may visually recognize the external light as in a mirror. To prevent such a phenomenon, the anti-reflection layer RPL may include color filters that display the same colors as pixels of the display panel DP.

External light may be filtered in the same colors as those of the pixels by the color filters. The external light may not be visible to the user. However, without being limited thereto, the anti-reflection layer RPL may include a polarizer film for decreasing the reflectivity of external light. The polarizer film may include a phase retarder and/or a polarizer.

The window WIN may be disposed on the anti-reflection layer RPL. The window WIN may protect the display panel DP, the input sensing part ISP, and the anti-reflection layer RPL from external scratches and impacts.

The panel protection film PPF may be disposed under the display panel DP. The panel protection film PPF may protect the bottom of the display panel DP. The panel protection film PPF may include a flexible plastic material such as polyethylene terephthalate (PET).

The first adhesive layer AL1 may be disposed between the display panel DP and the panel protection film PPF, and the display panel DP and the panel protection film PPF may be bonded to each other by the first adhesive layer ALL The second adhesive layer AL2 may be disposed between the window WIN and the anti-reflection layer RPL, and the window WIN and the anti-reflection layer RPL may be bonded to each other by the second adhesive layer AL2.

Referring to FIG. 5, the display panel DP may include a substrate SUB, a circuit element layer DP-CL disposed on the substrate SUB, a display element layer DP-OLED disposed on the circuit element layer DP-CL, and a thin film encapsulation layer TFE disposed on the display element layer DP-OLED.

The substrate SUB may include a display region DA and a non-display region NDA around the display region DA. The substrate SUB may include a flexible plastic material such as glass or polyimide (PI). The display element layer DP-OLED may be disposed on the display region DA.

Pixels may be disposed in the circuit element layer DP-CL and the display element layer DP-OLED. Each of the pixels may include a transistor disposed in the circuit element layer DP-CL and a light emitting element disposed in the display element layer DP-OLED and connected to the transistor.

The thin film encapsulation layer TFE may be disposed on the circuit element layer DP-CL to cover the display element layer DP-OLED. The thin film encapsulation layer TFE may protect the pixels from moisture, oxygen, and external foreign matter.

FIG. 6 is a schematic plan view of the display panel illustrated in FIG. 5.

For convenience of description, the first hole region HA1 and the second hole region HA2 are omitted.

Referring to FIG. 6, the display device DD may include the display panel DP, a scan driver SDV, the data driver DDV, and an emission driver EDV.

The display panel DP may include a first region AA1, a second region AA2, and a bending region BA between the first region AA1 and the second region AA2. The first region AA1, the bending region BA, and the second region AA2 may be arranged in the first direction DR1. The bending region BA may extend in the second direction DR2.

The first region AA1 may include a display region DA and a non-display region NDA around the display region DA. The non-display region NDA may surround the display region DA. The display region DA may be a region that displays an image, and the non-display region NDA may be a region that does not display an image. The second region AA2 and the bending region BA may be regions that do not display an image.

The first region AA1, when viewed in the second direction DR2, may include a first non-folding region NFA1, a second non-folding region NFA2, and a folding region FA between the first non-folding region NFA1 and the second non-folding region NFA2.

The display panel DP may include pixels PX, scan lines SL1 to SLm, data lines DL1 to DLn, emission lines EL1 to Elm, first and second control lines CSL1 and CSL2, a power line PL, connecting lines CNL, and pads PD, where “m” and “n” may be natural numbers. The pixels PX may be disposed in the display region DA and may be connected to the scan lines SL1 to SLm, the data lines DL1 to DLn, and the emission lines EL1 to Elm.

The scan driver SDV and the emission driver EDV may be disposed in the non-display region NDA. The scan driver SDV and the emission driver EDV may be disposed in the non-display regions NDA adjacent to opposite sides of the first region AA1 that are opposite each other in the second direction DR2. The data driver DDV may be disposed in the second region AA2. The data driver DDV may be manufactured in the form of an integrated circuit chip and may be mounted on the second region AA2.

The scan lines SL1 to SLm may extend in the second direction DR2 and may be connected to the scan driver SDV. The data lines DL1 to DLn may extend in the first direction DR1 and may be connected to the data driver DDV via the bending region BA. The emission lines EL1 to Elm may extend in the second direction DR2 and may be connected to the emission driver EDV.

The power line PL may extend in the first direction DR1 and may be disposed in the non-display region NDA. The power line PL may be disposed between the display region DA and the emission driver EDV. However, without being limited thereto, the power line PL may be disposed between the display region DA and the scan driver SDV.

The power line PL may extend to the second region AA2 via the bending region BA. The power line PL may extend toward a lower end of the second region AA2 in plan view. The power line PL may receive a drive voltage.

The connecting lines CNL may be arranged in the first direction DR1 and may extend in the second direction DR2. The connecting lines CNL may be connected to the power line PL and the pixels PX. The drive voltage may be applied to the pixels PX through the power line PL and the connecting lines CNL connected together.

The first control line CSL1 may be connected to the scan driver SDV and may extend toward the lower end of the second region AA2 via the bending region BA. The second control line CSL2 may be connected to the emission driver EDV and may extend toward the lower end of the second region AA2 via the bending region BA. The data driver DDV may be disposed between the first control line CSL1 and the second control line CSL2.

The pads PD may be disposed adjacent to the lower end of the second region AA2 in plan view. The data driver DDV, the power line PL, the first control line CSL1, and the second control line CSL2 may be connected to the pads PD.

The data lines DL1 to DLn may be connected to the corresponding pads PD through the data driver DDV. For example, the data lines DL1 to DLn may be connected to the data driver DDV, and the data driver DDV may be connected to the pads PD corresponding to the data lines DL1 to DLn.

Although not illustrated, a printed circuit board may be connected to the pads PD. A timing controller and a voltage generator may be disposed on the printed circuit board. The timing controller and the voltage generator may be connected to the pads PD through the printed circuit board.

The timing controller may control operations of the scan driver SDV, the data driver DDV, and the emission driver EDV. The timing controller may generate a scan control signal, a data control signal, and an emission control signal in response to control signals received from the outside. The voltage generator may generate the drive voltage.

The scan control signal may be provided to the scan driver SDV through the first control line CSL1. The emission control signal may be provided to the emission driver EDV through the second control line CSL2. The data control signal may be provided to the data driver DDV. The timing controller may receive image signals from the outside, may convert the data format of the image signals according to the specification of an interface with the data driver DDV, and may provide the converted signals to the data driver DDV.

The scan driver SDV may generate scan signals in response to the scan control signal. The scan signals may be applied to the pixels PX through the scan lines SL1 to SLm. The scan signals may be sequentially applied to the pixels PX.

The data driver DDV may generate data voltages corresponding to the image signals in response to the data control signal. The data voltages may be applied to the pixels PX through the data lines DL1 to DLn. The emission driver EDV may generate emission signals in response to the emission control signal. The emission signals may be applied to the pixels PX through the emission lines EL1 to Elm.

The pixels PX may receive the data voltages in response to the scan signals. The pixels PX may display an image by emitting light having luminance corresponding to the data voltages in response to the emission signals. Light emission time of the pixels PX may be controlled by the emission signals.

Although not illustrated, the bending area BA may be bent such that the second region AA2 is located under the first region AA1. Accordingly, the data driver DDV may be disposed under the first region AA1 and may not be visible from the outside.

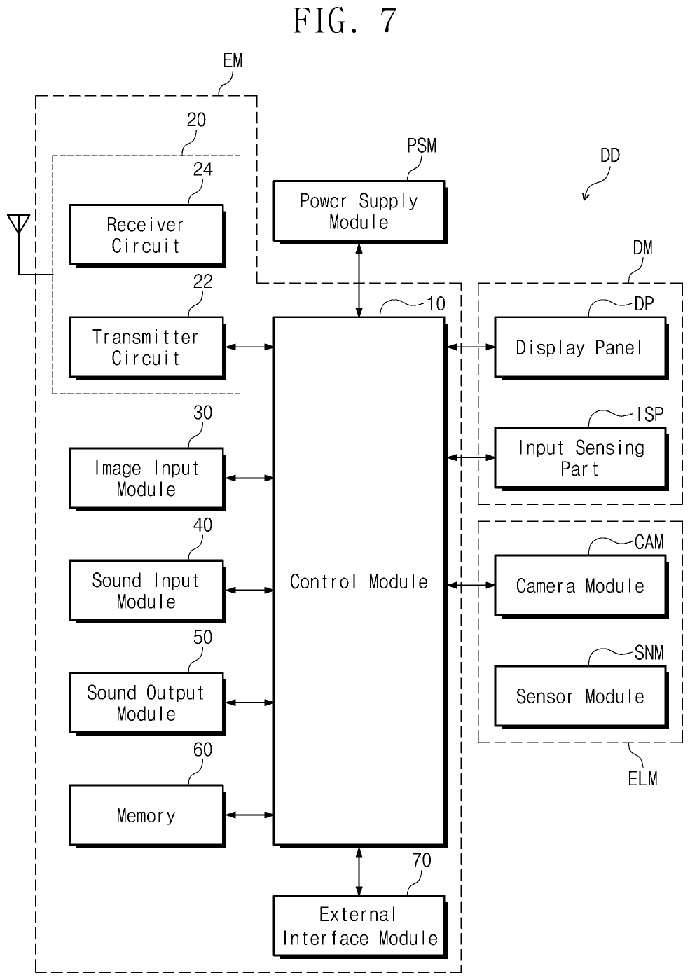

FIG. 7 is a schematic block diagram of the display device illustrated in FIG. 3.

Referring to FIG. 7, the display device DD may include the electronic module EM, the power supply module PSM, the display module DM, and an electro-optical module ELM. The electronic module EM may include a control module 10, a wireless communication module 20, an image input module 30, a sound input module 40, a sound output module 50, a memory 60, an external interface module 70, and the like. The modules may be mounted on a circuit board, or may be electrically connected through a flexible circuit board. The electronic module EM may be electrically connected with the power supply module PSM.

The control module 10 may control overall operation of the display device DD. For example, the control module 10 may activate or deactivate the display module DM in response to a user input. The control module 10 may control the image input module 30, the sound input module 40, and the sound output module 50 in response to a user input. The control module 10 may include at least one microprocessor.

The wireless communication module 20 may transmit/receive wireless signals with another terminal through Bluetooth or Wi-Fi. The wireless communication module 20 may transmit/receive sound signals using a general communication line. The wireless communication module 20 may include a transmitter circuit 22 that modulates a signal to be transmitted and transmits the modulated signal and a receiver circuit 24 that demodulates a received signal.

The image input module 30 may process an image signal to covert the image signal into image data that can be displayed on the display device DD. The sound input module 40 may receive an external sound signal through a microphone in a voice recording mode or a voice recognition mode and may convert the external sound signal into electrical voice data. The sound output module 50 may convert sound data received from the wireless communication module 20 or sound data stored in the memory 60 and may output the converted data to the outside.

The external interface module 70 may serve as an interface connected to an external charger, a wired/wireless data port, a card socket (e.g., a memory card or a SIM/UIM card), or the like.

The power supply module PSM may supply power required for overall operation of the display device DD. The power supply module PSM may include a battery device.

The electro-optical module ELM may be an electronic part that outputs or receives an optical signal. The electro-optical module ELM may transmit or receive an optical signal through a partial region of the display module DM. In this embodiment, the electro-optical module ELM may include a camera module CAM and a sensor module SNM. The camera module CAM may include the camera CA illustrated in FIG. 3. The sensor module SNM may include the sensor SN illustrated in FIG. 3.

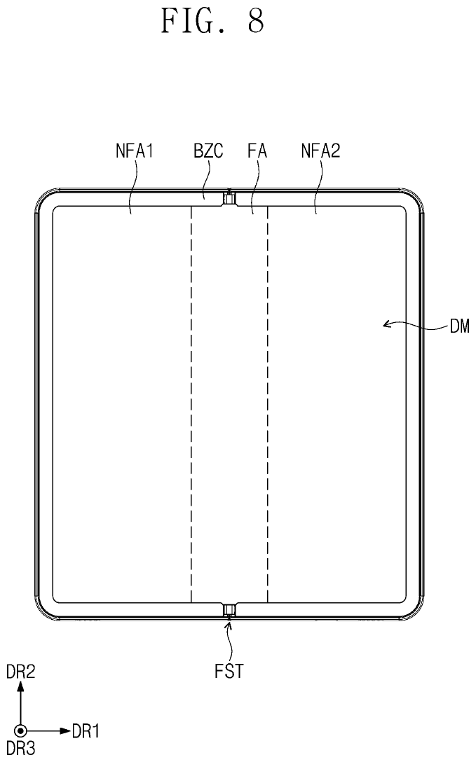

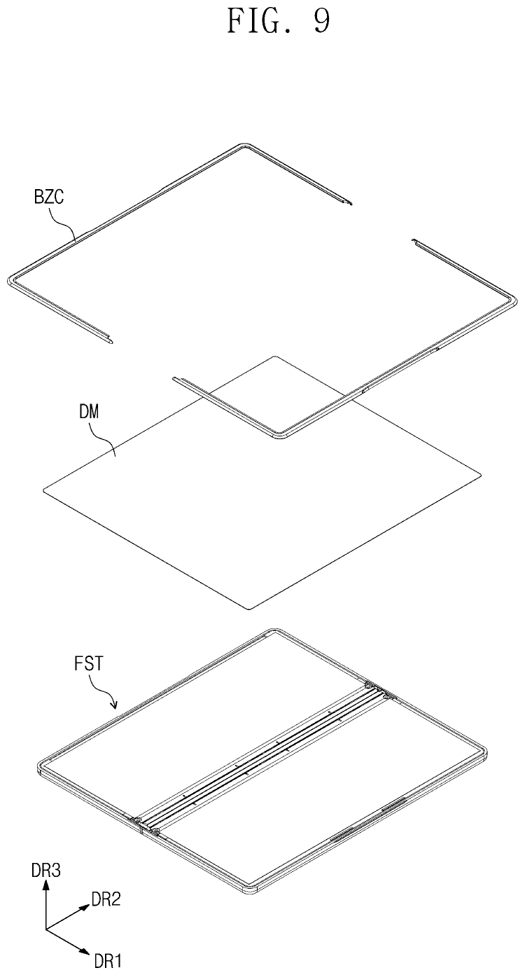

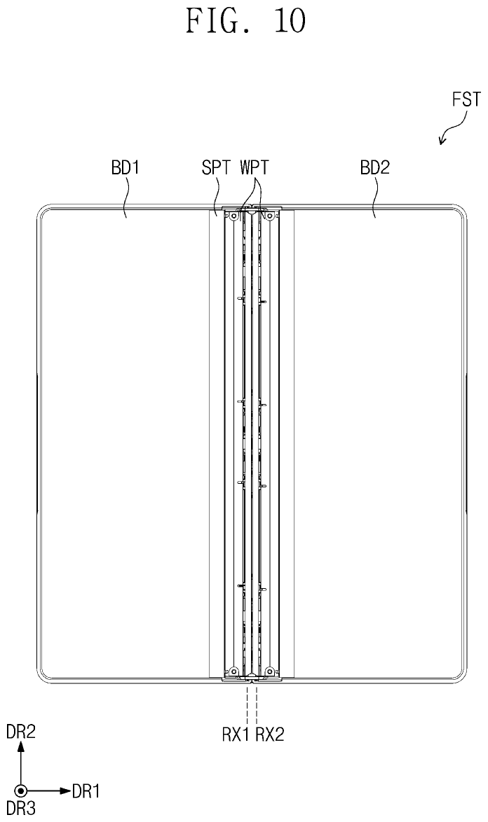

FIG. 8 is a more detailed schematic plan view of the display device illustrated in FIG. 1. FIG. 9 is an exploded schematic perspective view of the display device illustrated in FIG. 8. FIG. 10 is a schematic plan view of the folding set illustrated in FIG. 9.

Referring to FIGS. 8 and 9, the display device DD may include the display module DM, a bezel cover BZC disposed around the display module DM, and the folding set FST disposed under the display module DM and the bezel cover BZC.

The bezel cover BZC may be disposed around the first and second non-folding regions NFA1 and NFA2 of the display module DM. The bezel cover BZC may be disposed to surround the first and second non-folding regions NFA1 and NFA2 of the display module DM. The bezel cover BZC may be black in color, but the color of the bezel cover BZC is not limited thereto. The non-display region NDA of the display device DD illustrated in FIG. 1 may include the bezel cover BZC.

The folding set FST may support the display module DM and the bezel cover BZC. The folding set FST may be folded about biaxial rotational axes that are parallel to the second direction DR2 and that overlap the folding region FA in plan view and may fold the display module DM. This configuration will be described below in detail.

Although not illustrated in FIG. 9, the display module DM and the bezel cover BZC may be attached to the folding set FST by an adhesive.

Referring to FIGS. 9 and 10, the folding set FST may include a first body BD1, a second body BD2, wing plates WPT, and sub-plates SPT.

The first body BD1 and the second body BD2 may be arranged in the first direction DR1. The first body BD1 and the second body BD2 may have a plane defined by the first and second directions DR1 and DR2. The first body BD1 and the second body BD2 may have shapes symmetrical to each other in the first direction DR1. The above-described electronic module EM may be disposed in the first body BD1, and the above-described power supply module PSM may be disposed in the second body BD2.

The first body BD1 may be disposed under the first non-folding region NFA1 and may support the first non-folding region NFA1. The second body BD2 may be disposed under the second non-folding region NFA2 and may support the second non-folding region NFA2.

The wing plates WPT may be disposed on the first body BD1 and the second body BD2. The wing plates WPT may be arranged in the first direction DR1 and may extend in the second direction DR2. The wing plates WPT may be disposed under the folding region FA and may support the folding region FA. The wing plates WPT may be disposed between the first body BD1 and the second body BD2 and may be connected to the first body BD1 and the second body BD2.

The sub-plates SPT may extend in the second direction DR2 and may be disposed on opposite sides of the wing plates WPT that are opposite each other in the first direction DR1. The sub-plates SPT may be disposed between the wing plates WPT and the first body BD1 and between the wing plates WPT and the second body BD2. The sub-plates SPT may fill spaces between the first and second bodies BD1 and BD2 and the wing plates WPT.

The biaxial rotational axes RX1 and RX2 may extend in the second direction DR2. The biaxial rotational axes RX1 and RX2 may include the first rotational axis RX1 and the second rotational axis RX2 that are spaced apart from each other in the first direction DR1 and that extend in the second direction DR2. The first body BD1 and the second body BD2 may rotate about the biaxial rotational axes RX1 and RX2.

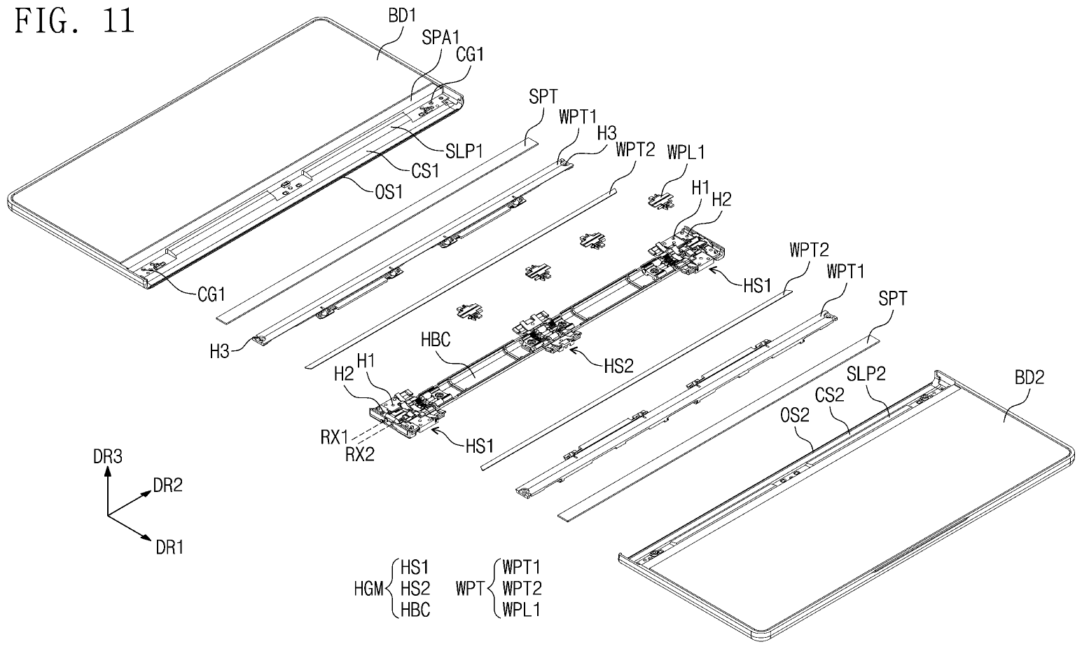

FIG. 11 is an exploded schematic perspective view of the folding set illustrated in FIG. 10.

Referring to FIG. 11, the wing plates WPT may include first wing plates WPT1, second wing plates WPT2, and first connecting parts WPL1. The second wing plates WPT2 may be disposed between the first wing plates WPT1. The second wing plates WPT2 may be closer to a central portion of a hinge module or assembly HGM than the first wing plates WPT1.

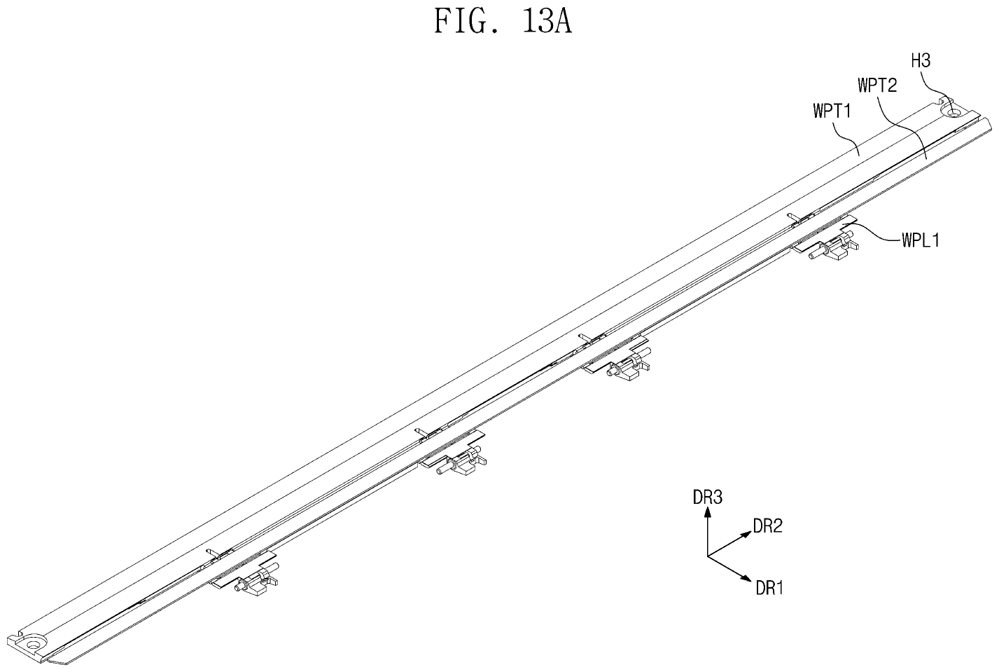

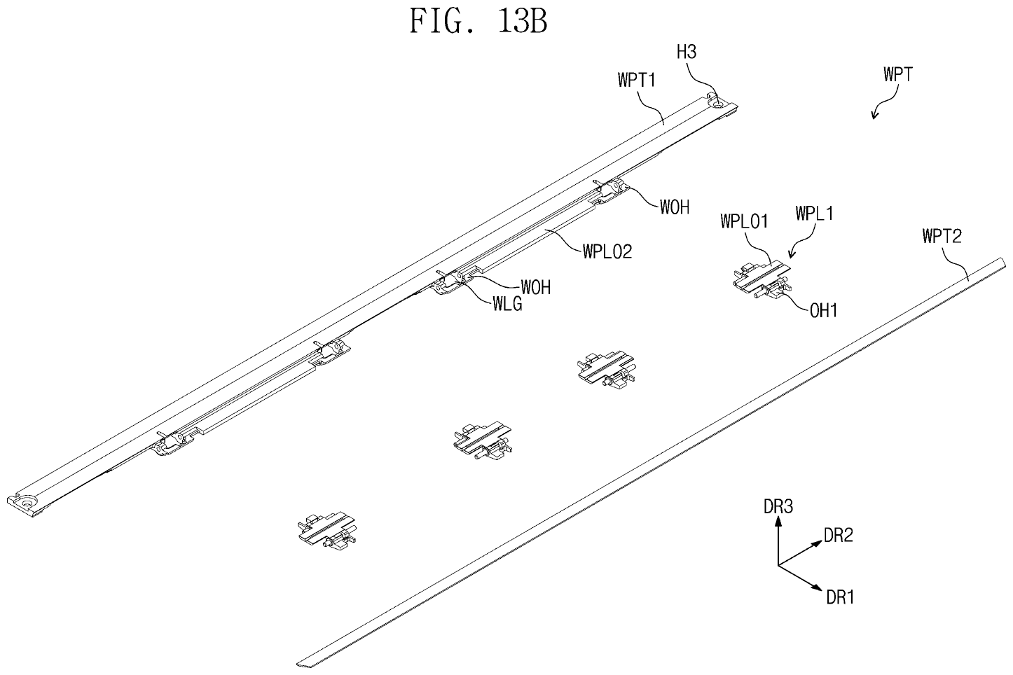

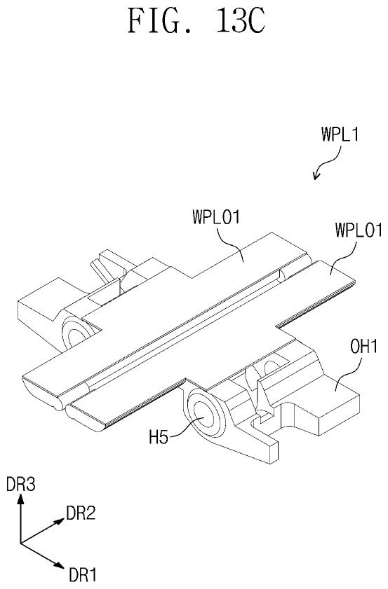

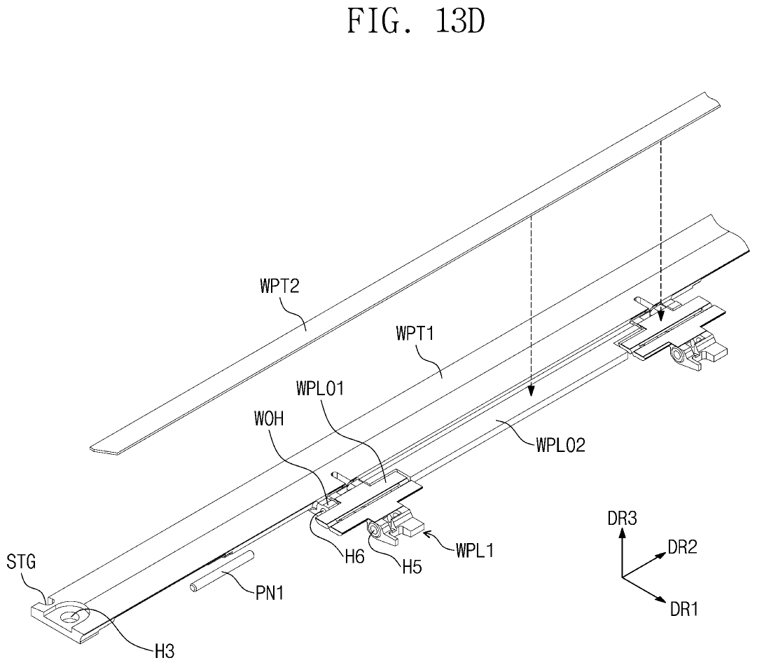

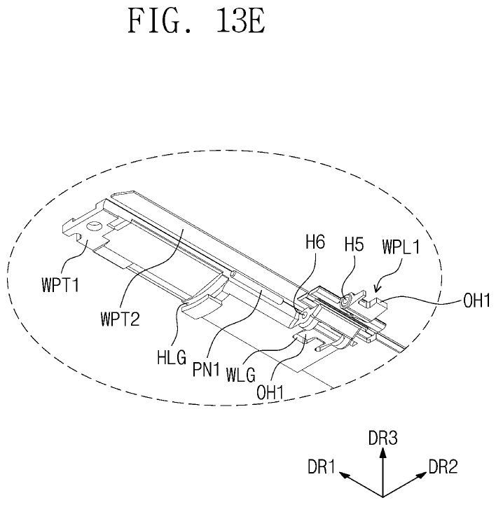

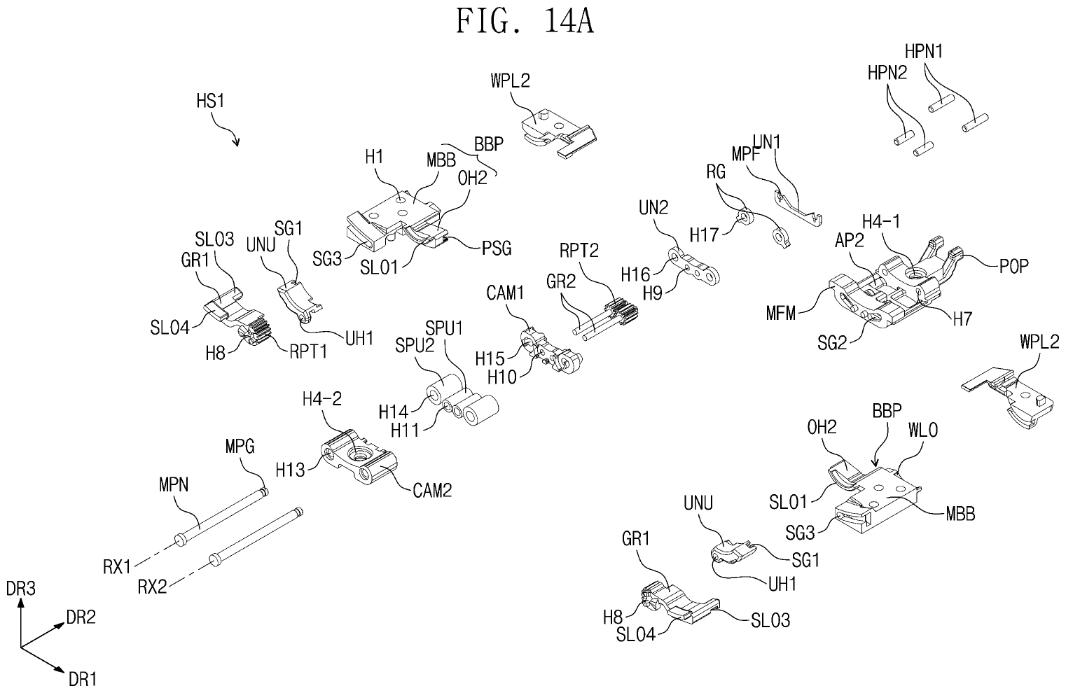

Although four first connecting parts WPL1 are illustrated as an example, the number of first connecting parts WPL1 is not limited thereto. The first connecting parts WPL1 may be arranged in the second direction DR2. The first connecting parts WPL1 may be disposed under the first wing plates WPT1 and the second wing plates WPT2. The first connecting parts WPL1 may be disposed over the hinge module HGM. The first wing plates WPT1 and the second wing plates WPT2 may be connected through the first connecting parts WPL1. A coupling relationship between the first wing plates WPT1 and the second wing plates WPT2 through the first connecting parts WPL1 will be described below in detail with reference to FIGS. 13A to 13E.

A first sub-body SPA1 may be defined on an upper surface of the first body BD1 that is adjacent to a side OS1 of the first body BD1. The first sub-body SPA1 may be formed to have a step with the first body BD1. The first body BD1 may extend in the second direction DR2.

The upper surface of the first body BD1 that is adjacent to the side OS1 of the first body BD1 may have a first inclined surface SLP1. The first inclined surface SLP1 may be closer to the side OS1 of the first body BD1 than the first sub-body SPA1. The first inclined surface SLP1 may have a decreasing height toward the side OS1 of the first body BD1. The first inclined surface SLP1 may be formed to have a step with an upper surface of the first sub-body SPA1 around the first inclined surface SLP1. The first inclined surface SLP1 may extend in the second direction DR2.

The upper surface of the first body BD1 between the first inclined surface SLP1 and the side OS1 of the first body BD1 may have a first curved portion CS1 having a curved shape. The first curved portion CS1 may extend from the first inclined surface SLP1 in the first direction DR1. The first curved portion CS1 may have a shape that is concave downward.

A second sub-body SPA2 may be defined on an upper surface of the second body BD2 that is adjacent to a side OS2 of the second body BD2. The second sub-body SPA2 may be formed to have a step with the second body BD2. The second body BD2 may extend in the second direction DR2.

The upper surface of the second body BD2 that is adjacent to the side OS2 of the second body BD2 may have a second inclined surface SLP2. The second inclined surface SLP2 may be closer to the side OS2 of the second body BD2 than the second sub-body SPA2. The second inclined surface SLP2 may have a decreasing height toward the side OS2 of the second body BD2. The second inclined surface SLP2 may be formed to have a step with an upper surface of the second sub-body SPA2 around the second inclined surface SLP2. The second inclined surface SLP2 may extend in the second direction DR2.

The upper surface of the second body BD2 between the second inclined surface SLP2 and the side OS2 of the second body BD2 may have a second curved portion CS2 having a curved shape. The second curved portion CS2 may extend from the second inclined surface SLP2 in the first direction DR1. The second curved portion CS2 may have a shape that is concave downward.

A sub-plate SPT may be disposed on the first sub-body SPA1 of the first body BD1, and the other sub-plate SPT may be disposed on the second sub-body SPA2 of the second body BD2. Each of the first wing plates WPT1 may be disposed on a corresponding one of the first inclined surface SLP1 and the second inclined surface SLP2. For example, one first wing plate WPT1 may be disposed on the first inclined surface SLP1, and the other first wing plate WPT1 may be disposed on the second inclined surface SLP2.

The hinge module HGM may be disposed under the wing plates WPT and the sub-plates SPT. The hinge module HGM may be disposed between the first body BD1 and the second body BD2. The hinge module HGM may be connected to opposite sides of the first body BD1 that are opposite each other in the second direction DR2 and opposite sides of the second body BD2 that are opposite each other in the second direction DR2.

The hinge module HGM may include first hinge parts HS1, a second hinge part HS2, and a hinge cover HBC. The first hinge parts HS1 and the second hinge part HS2 may be arranged in the second direction DR2. The first hinge parts HS1 may be spaced apart from each other in the second direction DR2 and may define opposite sides of the hinge module HGM. The second hinge part HS2 may be disposed between the first hinge parts HS1. The first hinge parts HS1 and the second hinge part HS2 may be connected to the first body BD1 and the second body BD2, and the first body BD1 and the second body BD2 may rotate about the first and second rotational axes RX1 and RX2 defined by the first hinge parts HS1 and the second hinge part HS2.

The first hinge parts HS1 may be disposed between the first body BD1 and the second body BD2. The first hinge parts HS1 may be connected to the opposite sides of the first and second bodies BD1 and BD2 that are opposite each other in the second direction DR2.

The second hinge part HS2 may be disposed between the first body BD1 and the second body BD2. The second hinge part HS2 may be connected to the center of the first body BD1 that is adjacent to the side OS1 of the first body BD1 and the center of the second body BD2 that is adjacent to the side OS2 of the second body BD2.

The first hinge parts HS1 may have first holes H1 defined therein. The first body BD1 and the second body BD2 may have first fastening recesses CG1 defined thereon. Screws (not illustrated) may pass through the first holes H1 and thereafter may be inserted into the first fastening recesses CG1 to connect the first and second hinge parts HS1 and HS2 to the first and second bodies BD1 and BD2.

The first hinge parts HS1 may have second holes H2 defined therein. The first wing plates WPT1 may have third holes H3 defined therein. Screws (not illustrated) may pass through the second holes H2 and the third holes H3 and may be connected to second fastening recesses CG2 defined on first brackets PB1 and second brackets PB2 to be described below with reference to FIG. 16. Accordingly, the wing plates WPT may be connected to the first hinge parts HS1 and the second hinge part HS2.

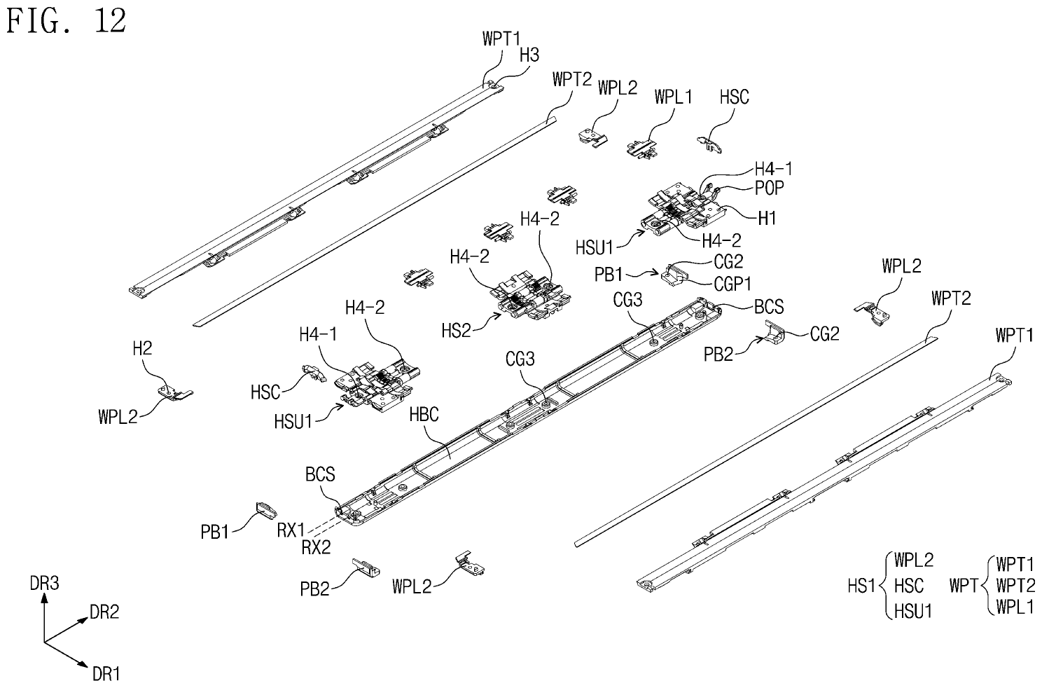

The hinge cover HBC may be disposed under the first hinge parts HS1 and the second hinge part HS2. The first hinge parts HS1 and the second hinge part HS2 may be connected to the hinge cover HBC. A connection relationship between the first hinge parts HS1, the second hinge part HS2, and the hinge cover HBC will be described below in detail with reference to FIG. 12.

FIG. 12 is an exploded schematic perspective view of the hinge module illustrated in FIG. 11.

The wing plates WPT and the sub-plates SPT of FIG. 12 may be identical or similar to the wing plates WPT and the sub-plates SPT of FIGS. 10 and 11 and therefore will be omitted from the description or will be briefly described.

For convenience of description, the first body BD1 and the second body BD2 are omitted.

Referring to FIG. 12, the first hinge parts HS1 may be disposed to be symmetrical to each other in the second direction DR2. The first hinge parts HS1 may include second connecting parts WPL2, first hinge units HSU1, and unit covers HSC.

Holes H4-1 and H4-2 may be defined in upper surfaces of the first hinge units HSU1 and the second hinge part HS2. Third fastening recesses CG3 may be defined on the hinge cover HBC. Screws (not illustrated) may pass through the fourth holes H4 and may be inserted into the third fastening recesses CG3 to connect the first hinge units HSU1 and the second hinge part HS2 to the hinge cover HBC.

The unit covers HSC may be disposed on the first hinge units HSU1 and may be connected to opposite sides of the hinge cover HBC that are opposite each other in the second direction DR2.

The first brackets PB1 and the second brackets PB2 may be disposed adjacent to the opposite sides of the hinge cover HBC that are opposite each other in the second direction DR2. The first brackets PB1 may be defined as brackets adjacent to the first rotational axis RX1. The second brackets PB2 may be defined as brackets adjacent to the second rotational axis RX2. The first brackets PB1 may be spaced apart from each other in the second direction DR2. The second brackets PB2 may be spaced apart from each other in the second direction DR2.

One pair of first and second brackets PB1 and PB2 may be connected to a side of a corresponding one of the first hinge parts HS1. The other pair of first and second brackets PB1 and PB2 may be connected to a side of the other first hinge part HS1. The side of the one first hinge part HS1 and the side of the other first hinge part HS1 may be disposed opposite each other in the second direction DR2 to define the opposite sides of the hinge module HGM described above.

The one pair of first and second brackets PB1 and PB2 may be disposed to be symmetrical to each other in the first direction DR1. The other pair of first and second brackets PB1 and PB2 may also be disposed to be symmetrical to each other in the first direction DR1.

The second connecting parts WPL2 may be disposed on the first hinge units HSU1 and may couple the first hinge units HSU1 to the first and second brackets PB1 and PB2 and the wing plates WPT. This configuration will be described below in detail. Screws (not illustrated) may pass through the second holes H2 defined in the second connecting parts WPL2 and the third holes H3 defined in the wing plates WPT and may be inserted into the second fastening recesses CG2 defined on the brackets PB1 and PB2.

One pair of second connecting parts WPL2 may be adjacent to one first hinge unit HSU1, and the other pair of second connecting parts WPL2 may be adjacent to the other first hinge unit HSU1. The one pair of second connecting parts WPL2 may be disposed to be symmetrical to each other in the first direction DR1. The other pair of second connecting parts WPL2 may be disposed to be symmetrical to each other in the first direction DR1.

The first wing plates WPT1 and the second wing plates WPT2 may be coupled by the first connecting parts WPL1, and a coupling relationship will be described below in detail with reference to FIGS. 13A to 13E.

FIGS. 13A to 13E are detailed schematic views illustrating a configuration of the wing plates illustrated in FIG. 11.

For example, FIGS. 13A to 13E are views illustrating a configuration of one wing plate WPT among the wing plates WPT illustrated in FIG. 11.

FIG. 13A is a perspective view of the wing plate WPT, and FIG. 13B is an exploded perspective view of the wing plate WPT. FIG. 13C is a perspective view of one first connecting part WPL1 illustrated in FIG. 13B. FIG. 13D is a view illustrating a coupled state of the first connecting part WPL1 and the first wing plate WPT1. FIG. 13E is an enlarged view illustrating the coupled state of the first connecting part WPL1 and the first wing plate WPT1 illustrated in FIG. 13D as viewed in a different direction.

Since the first connecting parts WPL1 may have the same or similar structure, one first connecting part WPL1 among the multiple first connecting parts WPL1 will be described.

Referring to FIG. 13A, the wing plate WPT may include the first wing plate WPT1, the second wing plate WPT2, and the first connecting parts WPL1. The first wing plate WPT1 and the second wing plate WPT2 may extend in the second direction DR2 and may be disposed adjacent to each other in the first direction and coupled to each other by the first connecting parts WPL1.

Referring to FIGS. 13b and 13c, the first connecting part WPL1 may include first connection seating parts WPLO1 and first protrusions OH1. The first connection seating parts WPLO1 may have a flat upper surface. The first connection seating parts WPLO1 may extend in the second direction DR2 and may be arranged in the first direction DR1. The first connection seating parts WPLO1 may have shapes symmetrical to each other in the first direction DR1.

The first protrusions OH1 may protrude outward from the first connection seating parts WPLO1. The first protrusions OH1 may have shapes symmetrical to each other in the first direction DR1. Fifth holes H5 may be defined in the first protrusions OH1, respectively. The fifth holes H5 may extend in the second direction DR2. The fifth holes H5 may be defined below the upper surfaces of the first connection seating parts WPLO1.

The wing plate WPT may include wing connecting protrusions I and second connection seating parts WPLO2. The wing connecting protrusions WOH may protrude from one of opposite sides of the first wing plate WPT1 that are opposite each other in the first direction DR1. The wing connecting protrusions WOH may protrude from a side of the first wing plate WPT1 in the first direction DR1. The side of the first wing plate WPT1 may be adjacent to the first connecting part WPL1. The wing connecting protrusions WOH may protrude toward the first connecting part WPL1.

The wing connecting protrusions WOH may be arranged in the second direction DR2 on the side of the first wing plate WPT1. For example, four wing connecting protrusions WOH corresponding to four first connecting parts WPL1 are illustrated in FIG. 13B. However, the number of wing connecting protrusions WOH may vary depending on the number of first connecting parts WPL1. Hereinafter, one wing connecting protrusion WOH will be described.

A wing connecting recess WLG may be defined on an upper surface of the wing connecting protrusion WOH. The second connection seating part WPLO2 may be formed on the side of the first wing plate WPT1. The second connection seating part WPLO2 may be formed between the wing connecting protrusions WOH.

The second connection seating parts WPLO2 may protrude from the side of the first wing plate WPT1. The second connection seating parts WPLO2 may protrude toward the first connecting part WPL1.

Hereinafter, a coupling relationship between one first connecting part WPL1 and one wing connecting protrusion WOH will be described as an example.

Referring to FIGS. 13D and 13E, the wing connecting recess WLG may be defined on a side of the wing connecting protrusion WOH that is adjacent to the first protrusion OH1 of the first connecting part WPL1. The first protrusion OH1 may be inserted into the wing connecting recess WLG. A sixth hole H6 may be defined in the wing connecting protrusion WOH. The sixth holes H6 may extend in the second direction DR2. The fifth hole H5 and the sixth hole H6 may overlap each other in the second direction DR2.

A first pin PN1 may be inserted into the fifth hole H5 and the sixth hole H6, and the first connecting part WPL1 and the first wing plate WPT1 may be coupled to each other by the first pin PN1. The first connecting part WPL1 may be rotatably connected to the first wing plate WPT1 by the first pin PN1.

The second wing plate WPT2 may be disposed on the upper surfaces of the first connection seating parts WPLO1 and the upper surfaces of the second connection seating parts WPLO2. The second wing plate WPT2 may be attached to the upper surfaces of the first and second connection seating parts WPLO1 and WPLO2 by an adhesive. Since the first connecting part WPL1 is coupled to rotate relative to the first wing plate WPT1, the second wing plate WPT2 may rotate together with the first connecting part WPL1 in case that the first connecting part WPL1 rotates. Accordingly, the second wing plate WPT2 may be rotatably coupled to the first wing plate WPT1 by the first connecting part WPL1.

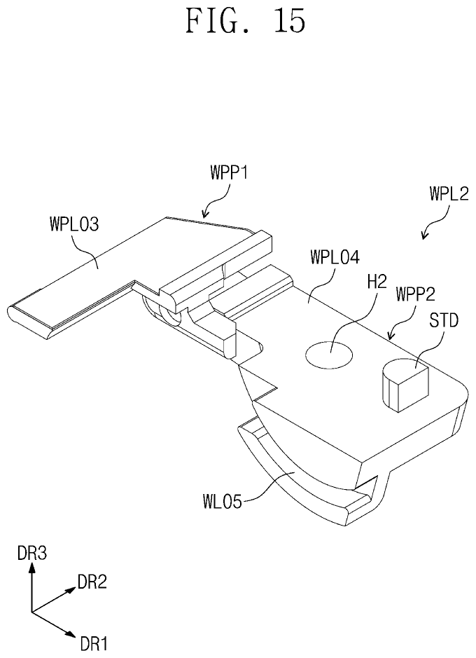

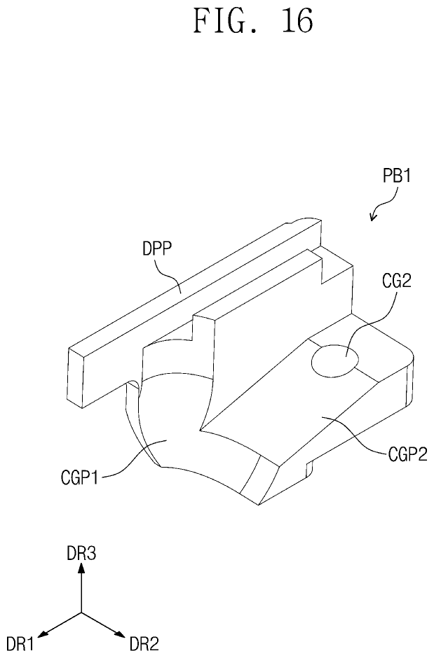

A fixing recess STG may be defined on an opposite side of the first wing plate WPT1 that is opposite the side of the first wing plate WPT1 to which the first connecting part WPL1 is coupled. The fixing recess STG may be adjacent to the third hole H3. The fixing recess STG will be described below in detail with reference to FIG. 15.

Referring to FIG. 13E, a hinge connecting recess HLG may be defined on a lower surface of the first wing plate WPT1. The hinge module HGM illustrated in FIG. 11 may be coupled to the hinge connecting recess HLG. A connection relationship between the hinge connecting recess HLG and the hinge module HGM will be described below in detail.

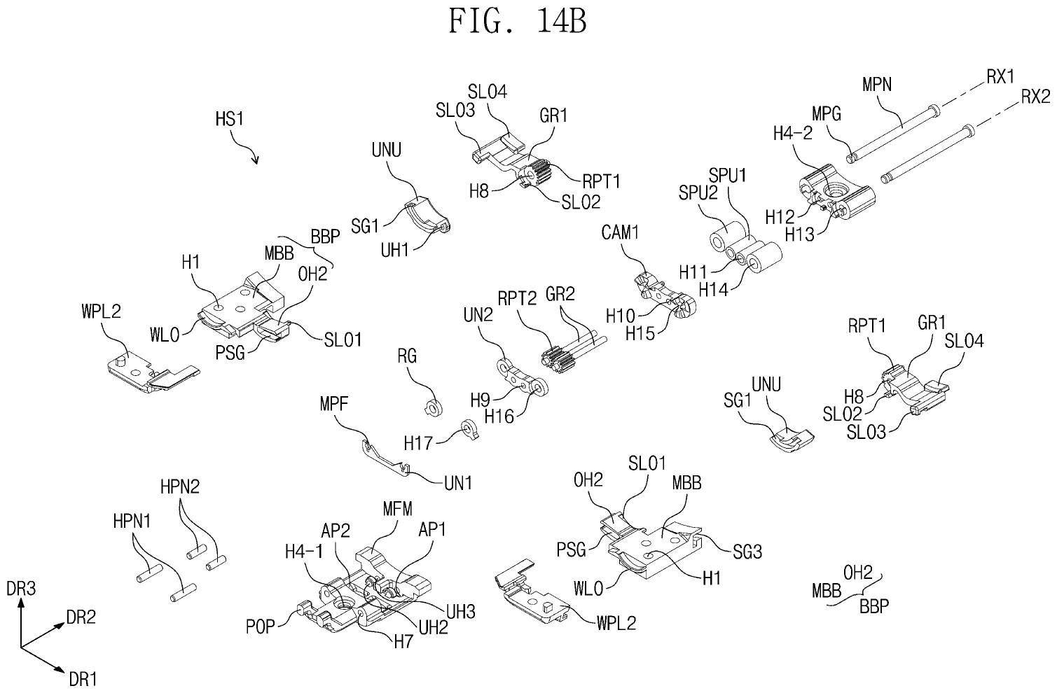

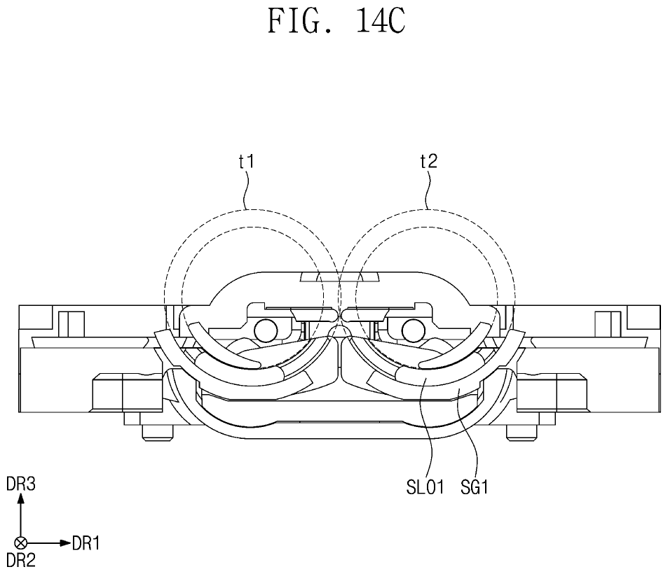

FIGS. 14A to 14C are schematic views illustrating detailed components of the first hinge part HS1. FIG. 15 is a schematic perspective view of the second connecting part illustrated in FIGS. 14A and 14B.

FIGS. 14A and 14B are exploded perspective views of the first hinge parts symmetrical to each other in the second direction DR2. FIG. 14C is a view illustrating sections of first sliding protrusions SLO1 of sub-frames BPP and first sliding grooves SG1 of coupling units or pieces UNU.

Hereinafter, FIGS. 14A to 14C will be described together with FIGS. 13A to 13E according to the need for description.

Referring to FIGS. 14A to 14C, each of the first hinge parts HS1 may include a main frame MFM, protrusions POP, a pair of coupling units UNU, a first unit UN1, a second unit UN2, a pair of sub-frames BBP, a pair of second connecting parts WPL2, a pair of ring units RG, a pair of first gear parts GR1, a pair of second gear parts GR2, a first cam part CAM1, a second cam part CAM2, spring units SPU1 and SPU2, and a pair of main pins MPN.

FIGS. 14A and 14B illustrate the first hinge parts HS1 symmetrical to each other and having substantially the same or similar configuration. Therefore, components of the first hinge part HS1 illustrated in FIG. 14A will be described, and components not illustrated in FIG. 14A will be described with reference to FIG. 14B.

The protrusions POP may protrude from the main frame MFM in the second direction DR2. The protrusions POP may protrude from a side of the main frame MFM that faces toward the outside of the hinge module HGM in the second direction DR2. The protrusions POP may be spaced apart from each other in the first direction DR1. Although two protrusions POP are illustrated as an example, the number of protrusions POP is not limited thereto. The protrusions POP may be integrally formed with the main frame MFM. However, without being limited thereto, the protrusions POP may be manufactured separately from the main frame MFM and may be coupled to the main frame MFM.

A hole H4-1 may be defined in an upper surface of the main frame MFM. The hole H4-1 may extend in the third direction DR3. A screw (not illustrated) may pass through the hole H4-1 and may be inserted into the third fastening recess CG3 defined on the hinge cover HBC of FIG. 12.

The coupling units UNU may be disposed on first portions AP1 (illustrated in FIG. 14B) that are defined on the upper surface of the main frame MFM and disposed in the first direction DR1. Each of the coupling units UNU may be disposed on a corresponding one of the first portions AP1. The coupling units UNU may be disposed to be symmetrical to each other in the first direction DR1. The first sliding groove SG1 may be defined on one of opposite sides of the coupling unit UNU that are opposite each other in the second direction DR2. The first sliding groove SG1 may have a curved shape.

A first coupling hole UH1 may be defined on an opposite side of the coupling unit UNU. Second coupling holes UH2 and third coupling holes UH3 may be defined adjacent to the first portions AP1 of the main frame MFM. The first coupling holes UH1, the second coupling holes UH2, and the third coupling holes UH3 may extend in the second direction DR2. The first coupling holes UH1 may be disposed between the second coupling holes UH2 and the third coupling holes UH3. When viewed in the second direction DR2, the first coupling holes UH1, the second coupling holes UH2, and the third coupling holes UH3 may overlap.

Second sliding grooves SG2 (illustrated in FIG. 14B) may be defined on an opposite side of the main frame MFM that is opposite the side of the main frame MFM in the second direction DR2. The main pins MPN to be described below may be inserted into the second sliding grooves SG2.

The sub-frames BBP may be disposed on the main frame MFM so as to be symmetrical to each other in the first direction DR1. The sub-frames BBP may be disposed on second portions AP2 that are defined on the upper surface of the main frame MFM and disposed in the first direction DR1. The second portions AP2 may be defined as depressions.

Each of the sub-frames BBP may include a main body MBB, a second protrusion OH2, and a coupling portion WLO. First holes H1 may be defined in upper surfaces of the main bodies MBB. The first holes H1 may extend in the third direction DR3. The first holes H1 may overlap the first fastening recesses CG1 of FIG. 11 in the third direction DR3.

A third sliding groove SG3 may be defined on one of opposite sides of the main body MBB that are opposite each other in the second direction DR2. The coupling portion WLO may protrude in the second direction DR2 from an opposite side of the main body MBB that is opposite the side of the main body MBB in the second direction DR2.

The second protrusions OH2 may extend from the main bodies MBB in the first direction DR1. The second protrusions OH2 may extend from the main bodies MBB in directions facing each other. The first sliding protrusion SLO1 may protrude in the second direction DR2 from one of opposite sides of the second protrusion OH2 that are opposite each other in the second direction DR2. A pin sliding groove PSG may be defined on an opposite side of the first sliding protrusion SLO1.

Each of the first sliding protrusions SLO1 of the second protrusions OH2 may be coupled to a corresponding one of the first sliding grooves SG1 of the coupling units UNU. The coupling units UNU may connect the sub-frames BBP to the main frame MFM. The first sliding protrusions SLO1 may reciprocate along the first sliding grooves SG1. For example, in case that the first gear parts GP1 to be described below rotate, the first sliding protrusions SLO1 may move along a first path t1 and a second path t2 as illustrated in FIG. 14C.

Seventh holes H7 may be defined on one of opposite sides of the main frame MFM that are opposite each other in the second direction DR2. The seventh holes H7 may extend in the second direction DR2. The seventh holes H7 may be defined to be symmetrical to each other in the first direction DR1.

First hinge pins HPN1 may pass through the seventh holes H7 and may be coupled to the pin sliding grooves PSG. In case that the first sliding protrusions SLO1 reciprocate along the first sliding grooves SG1, the pin sliding grooves PSG may reciprocate with respect to the first hinge pins HPN1.

The second hinge pins HPN2 may be arranged in the first direction DR1 and may extend in the second direction DR2. The second hinge pins HPN2 may be inserted into the first coupling holes UH1, the second coupling holes UH2, and the third coupling holes UH3. The second hinge pins HPN2 may connect the coupling units UNU to the main frame MFM.

The first unit UN1, the ring units RG, and the second unit UN2 may be disposed on the opposite side of the main frame MFM that is opposite the side of the main frame MFM from which the protrusions POP protrude in the second direction DR2. The second sliding grooves SG2 of the main frame MFM may face the first unit UN1. The main frame MFM, the first unit UN1, the ring units RG, and the second unit UN2 may be arranged in the second direction DR2. The ring units RG may be disposed between the first unit UN1 and the second unit UN2. The ring units RG may be disposed to be symmetrical to each other in the first direction DR1.

The first gear parts GR1 may be disposed to be symmetrical to each other in the first direction DR1. The first gear parts GR1 may be connected to the opposite side of the main frame MFM that is opposite the side of the main frame MFM from which the protrusions POP protrude. The main frame MFM, the first unit UN1, the ring units RG, the second unit UN2, and the first gear parts GR1 may be arranged in the second direction DR2. The sub-frames BBP and the first gear parts GR1 may be arranged in the second direction DR2.

The first gear parts GR1 may include second sliding protrusions SLO2, third sliding protrusions SLO3, fourth sliding protrusions SLO4, and first protrusions RPT1. The second sliding protrusion SLO2 and the third sliding protrusion SLO3 may protrude from one of opposite sides of the first gear part GR1 that are opposite each other in the second direction DR2. The second sliding protrusion SLO2 and the third sliding protrusion SLO3 may protrude in the second direction DR2 from the side of the first gear part GR1. The fourth sliding protrusion SLO4 may protrude in the second direction DR2 from an opposite side of the first gear part GR1.

The first gear part GR1 may include the first protrusions RPT1 on one of opposite sides of the first gear part GR1 that are opposite each other in the first direction DR1. An eighth hole H8 may be defined on a side of the first gear part GR1. The eighth hole H8 may extend in the second direction DR2. The protrusions RPT1 may surround the eighth hole H8. The eighth hole H8 may overlap a corresponding one of the biaxial rotational axes RX1 and RX2. The first gear parts GR1 facing each other may rotate in opposite directions about the biaxial rotational axes RX1 and RX2.

The third sliding protrusions SLO3 of the first gear parts GR1 may be connected to the third sliding grooves SG3 of the sub-frames BBP. As the third sliding protrusions SLO3 are connected to the third sliding grooves SG3, the sub-frames BBP may be rotated about the first rotational axis RX1 and the second rotational axis RX2 in case that the first gear parts GR1 rotate.

Referring to FIGS. 14A and 13E, the fourth sliding protrusions SLO4 of the first gear parts GR1 may be connected to the hinge connecting recess HLG defined on the lower surface of the first wing plate WPT1 of FIG. 13E. Accordingly, in case that the first gear parts GR1 rotate about the first rotational axis RX1 and the second rotational axis RX2, the first wing plates WPT1 may also be rotated.

The second gear parts GR2 may be spaced apart from each other in the first direction DR1 and may extend in the second direction DR2. The second gear parts GR2 may be connected to the second unit UN2. Ninth holes H9 may be defined in the second unit UN2 so as to be spaced apart from each other in the first direction DR1. The ninth holes H9 may extend in the second direction DR2. Each of the second gear parts GR2 may be inserted into a corresponding one of the ninth holes H9.

Each of the second gear parts GR2 may include second protrusions RPT2 on a side thereof that is adjacent to the main frame MFM in the second direction DR2. The second protrusions RPT2 may be engaged with each other and may rotate together.

Each of the first protrusions RPT1 of the first gear parts GR1 may be engaged to rotate together with a corresponding second protrusion RPT2 among the second protrusions RPT2 of the second gear parts GR2. One pair of first and second protrusions RPT1 and RPT2 may rotate in opposite directions. Another pair of first and second protrusions RPT1 and RPT2 may rotate in opposite directions.

Tenth holes H10 spaced apart from each other in the first direction DR1 and extending in the second direction DR2 may be defined in the first cam part CAM1. Eleventh holes H11 spaced apart from each other in the first direction DR1 and extending in the second direction DR2 may be defined in the centers of the first spring units SPU1. Twelfth holes H12 (illustrated in FIG. 14B) that are spaced apart from each other in the first direction DR1 and that extend in the second direction DR2 may be defined in the second cam part CAM2. Substantially, the twelfth holes H12 may be fastening recesses.

An opposite side of the second gear part GR2 in the second direction DR2 may pass through the first cam part CAM1 and the first spring unit SPU1 and may be coupled to the second cam part CAM2. For example, the opposite side of the second gear part GR2 may pass through the tenth hole H10 defined in the first cam part CAM1 and the eleventh hole H11 of the first spring unit SPU1 and may be coupled to the twelfth hole H12 defined in the second cam part CAM2.

The main pins MPN may be spaced apart from each other in the first direction DR1 and may extend in the second direction DR2. A hook groove MPG may be defined on a side of the main pin MPN that faces the main frame MFM in the second direction DR2.

Thirteenth holes H13 spaced apart from each other in the first direction DR1 and extending in the second direction DR2 may be defined in the second cam part CAM2. The twelfth holes H12 may be defined between the thirteenth holes H13. Fourteenth holes H14 may be defined in the centers of the second spring units SPU2. The fourteenth holes H14 may extend in the second direction DR2. Fifteenth holes H15 spaced apart from each other in the first direction DR1 and extending in the second direction DR2 may be defined in the first cam part CAM1. The tenth holes H10 may be defined between the fifteenth holes H15. Sixteenth holes H16 spaced apart from each other in the first direction DR1 and extending in the second direction DR2 may be defined in the second unit UN2. The ninth holes H9 may be defined between the sixteenth holes H16. Seventeenth holes H17 may be defined in the centers of the ring units RG. Hook portions MPF spaced apart from each other in the first direction DR1 may be defined in the first unit UN1.

Each of the main pins MPN may pass through corresponding holes among the thirteenth holes H13 of the second cam part CAM2, the fourteenth hole H14 of the second spring unit SPU2, the fifteenth holes H15 of the first cam part CAM1, the sixteenth holes H16 of the second unit UN2, and the seventeenth holes H17 of the ring units RG and may be coupled to the second sliding groove S G2 defined on the opposite side of the main frame MFM. Each of the hook grooves MPG of the main pins MPN may be coupled to a corresponding hook portion MPF among the hook portions MPF defined in the first unit UN1.

The main pins MPN may define the first rotational axis RX1 and the second rotational axis RX2. The main pins MPN may provide the first rotational axis RX1 and the second rotational axis RX2 to the sub-frames BBP, the first body BD1, and the second body BD2.

Referring to FIG. 15, the second connecting parts WPL2 may be disposed on the first hinge units HSU1 as illustrated in FIG. 11. One pair of second connecting parts WPL2 may be adjacent to one first hinge unit HSU1. Another pair of second connecting parts WPL2 may be adjacent to another first hinge unit HSU1. The one pair of second connecting parts WPL2 may be disposed to be symmetrical to each other in the first direction DR1. The other pair of second connecting parts WPL2 may be disposed to be symmetrical to each other in the first direction DR1.

Since the second connecting parts WPL2 may have the same or similar configuration, any one second connecting part WPL2 will be described below with reference to FIG. 15.

The second connecting part WPL2 may include a first portion WPP1 and a second portion WPP2. The first portion WPP1 and the second portion WPP2 may be coupled so as to be rotated.

A third connection seating part WPLO3 may be defined on an upper surface of the first portion WPP1. A fourth connection seating part WPLO4 may be defined on an upper surface of the second portion WPP2. A second hole H2 may be defined in the fourth connection seating part WPLO4. The second hole H2 may extend in the third direction DR3. The second portion WPP2 may include a fixed protrusion STD having a semicircular shape. The fixed protrusion STD may be adjacent to an opposite side of the second portion WPP2 that is opposite a side of the second portion WPP2 that is coupled with the first portion WPP1.

Hereinafter, a connection relationship between one second coupling part WPL2, one first wing plate WPT1, one second coupling part WPL2, and a sub-frame BBP will be described.

Referring to FIGS. 13D and 15, the second connecting part WPL2 may be disposed under the wing plate WPT of FIG. 13B. The second wing plate WPT2 of FIG. 13B may be disposed on the third connection seating part WPLO3. The first wing plate WPT1 may be disposed on the fourth connection seating part WPLO4.

In case that the first wing plate WPT1 is disposed on the fourth connection seating part WPLO4, the fixed protrusion STD may be disposed in the fixing recess STG of FIG. 13D.

A screw (not illustrated) may pass through the third hole H3 defined in the first wing plate WPT1 of FIG. 13D and the second hole H2 defined in the fourth connection seating part WPLO4. The second connecting part WPL2 and the first wing plate WPT1 may be coupled by the screw.

Referring to FIGS. 14A and 15, the second portion WPP2 may include a fifth sliding protrusion SLO5. The fifth sliding protrusion SLO5 may be located under the fourth connection seating part WPLO4.

The fifth sliding protrusion SLO5 may be coupled to the coupling portion WLO formed in the main body MBB illustrated in FIG. 14A. The fifth sliding protrusion SLO5 may be connected to the corresponding coupling portion WLO, and the upper surface of the fifth sliding protrusion SLO5 may move along the lower surface of the coupling portion WLO.

Referring to FIGS. 14A and 15, the second connecting part WPL2 may be connected to the sub-frame BBP. The wing plate WPT may be connected to the second connecting part WPL2. The wing plate WPT may be connected to the sub-frame BBP by the second connecting part WPL2. Accordingly, in case that the sub-frame BBP rotates, the fifth sliding protrusion SLO5 may be moved along the coupling portion WLO, and the wing plate WPT may be rotated.

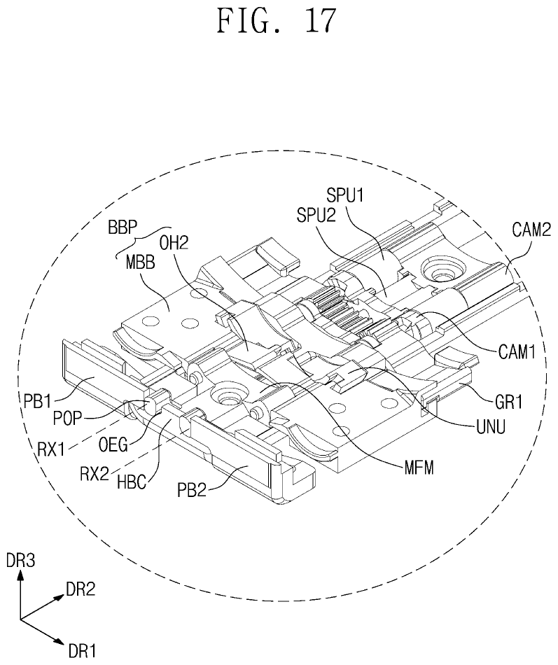

FIG. 16 is a schematic perspective view of the bracket illustrated in FIG. 12. FIG. 17 is an enlarged schematic perspective view of the brackets coupled to the first hinge unit.

The first bracket PB1 and the second bracket PB2 may have substantially the same or similar configuration, except that the first bracket PB1 and the second bracket PB2 are symmetrical to each other in the first direction DR1. Therefore, one first bracket PB1 is illustrated and described in FIG. 16.

The first hinge parts HS1 may have substantially the same or similar configuration, and therefore only one of the first hinge parts HS1 will be described below.

For convenience of description, FIG. 17 illustrates a state in which the second connecting parts WPL2 are not coupled.

Referring to FIG. 16, the first bracket PB1 may include a first surface CGP1, a second surface cGP2, and a flat protruding portion DPP.

The first surface CGP1 may be a surface having a concave shape. The second surface CGP2 may include a flat surface and an inclined surface extending from the flat surface. The inclined surface may have the same inclination angle as the first inclined surface SLP1 and the second inclined surface SLP2 of FIG. 11.

The second fastening recess CG2 may be defined on the second surface CGP2. The second fastening recess CG2 may extend in the third direction DR3. The second fastening recess CG2 may overlap the second hole H2 and the third hole H3 of FIG. 11, and a screw (not illustrated) may pass through the second hole H2 and the third hole H3 and may be inserted into the second fastening recess CG2.

The flat protruding portion DPP may have a plane defined by the first direction DR1 and the third direction DR3. As illustrated in FIG. 17, flat protruding portions DPP may extend in directions facing each other.

Referring to FIGS. 11, 16, and 17, the first surfaces CGP1 of the first and second brackets PB1 and PB2 may be adjacent to opposite sides of the hinge cover HBC that are opposite each other in the first direction DR1. As illustrated in FIG. 17, the first bracket PB1 and the second bracket PB2 may be disposed on opposite sides of the first hinge part HS1 that are opposite each other in the first direction DR1.

Exposure recesses OEG may be defined in the hinge cover HBC. The exposure recesses OEG may overlap the protrusions POP. The number of exposure recesses OEG may be the same as the number of protrusions POP.

The protrusions POP may be disposed in the exposure recesses OEG. The protrusions POP may protrude outward through the exposure recesses OEG. The protrusions POP may be disposed between the biaxial rotational axes RX1 and RX2.

The flat protruding portions DPP may be disposed to be symmetrical to each other in the first direction DR1. The flat protruding portions DPP may be disposed on the opposite sides of the first hinge part HS1. The protrusions POP may be disposed between the first and second brackets PB1 and PB2. The flat protruding portions DPP may extend in the first direction DR1 toward the protrusions POP. Sides of the flat protruding portions DPP that face each other may make contact with the protrusions POP. The sides of the flat protruding portions DPP may face the protrusions POP.

A side of the first bracket PB1 and a side of the second bracket PB2 that face each other in the first direction DR1 may be defined by the sides of the flat protruding portions DPP that face each other. For example, the side of the first bracket PB1 and the side of the second bracket PB2 may make contact with the protrusions POP.

Referring to FIGS. 15 and 17, each of the first and second brackets PB1 and PB2 may be connected to the first hinge part HS1 by a corresponding one of the second connecting parts WPL2. Each of the first and second brackets PB1 and PB2 may be coupled to a corresponding one of the second connecting parts WPL2 connected to the sub-frames BBP. Accordingly, in case that the sub-frames BBP rotate, the first and second brackets PB1 and PB2 may be rotated together.

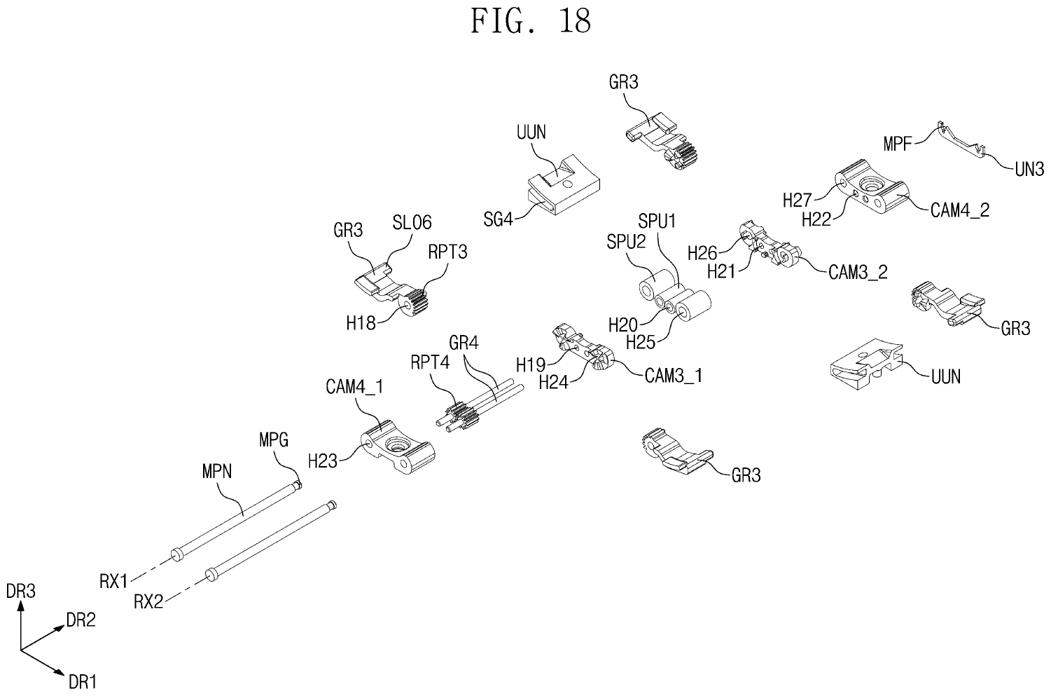

FIG. 18 is an exploded schematic perspective view of the second hinge part.

Referring to FIG. 18, the second hinge part HS2 may include third cams CAM3_1 and CAM3_2, fourth cams CAM4_1 and CAM4_2, assembly units UUN, a third unit UN3, and third gear parts GR3.

One pair of third gear parts GR3 may be connected to opposite sides of one assembly unit UUN corresponding thereto among the assembly units UUN. Another pair of third gear parts GR3 may be connected to opposite sides of another assembly unit UUN corresponding thereto among the assembly units UUN.

The third gear parts GR3 may include sixth sliding protrusions SLO6 and third protrusions RPT3. The sixth sliding protrusion SLO6 may extend in the second direction DR2 from one of opposite sides of the third gear part GR3 that are opposite each other in the second direction DR2.

The third gear part GR3 may include the third protrusion RPT3 on one of opposite sides of the third gear part GR3 that are opposite each other in the first direction DR1. An eighteenth hole H18 may be defined on the side of the third gear part GR3. The eighteenth hole H18 may extend in the second direction DR2. The third protrusion RPT3 may surround the eighteenth hole H18. The eighteenth hole H18 may overlap a corresponding one of the biaxial rotational axes RX1 and RX2.

A fourth sliding groove SG4 may be defined on one of opposite sides of the assembly unit UUN that are opposite each other in the second direction DR2. The sixth sliding protrusion SLO6 may be connected to the fourth sliding groove SG4. Accordingly, in case that the third gear parts GR3 rotate, the assembly units UUN may be rotated together.

Fourth gear parts GR4 may be disposed between the third gear parts GR3. The fourth gear parts GR4 may be spaced apart from each other in the first direction DR1. The fourth gear parts GR4 may be disposed between the cam CAM3_1 and the cam CAM4_1. Spring units SPU1 and SPU2 may be disposed between the cam CAM3_1 and the cam CAM3_2. The cam CAM4_2 may be disposed between the cam CAM3_2 and the third unit UN3. The fourth gear parts GR4, the cam CAM3_1, the spring units SPU1 and SPU2, the cam CAM3_2, the cam CAM4_2, and the third unit UN3 may be arranged in the second direction DR2.

One of opposite sides of the fourth gear part GR4 that are opposite each other in the second direction DR2 may be inserted into a hole (not illustrated) that is formed in the cam CAM4_1.

The fourth gear part GR4 may include a fourth protrusion RPT4 on an opposite side of the fourth gear part GR4 that is adjacent to the cam CAM4_1. The third protrusions RPT3 of the third gear parts GR3 and the fourth protrusions RPT4 of the fourth gear parts GR4 may be engaged with each other to rotate.

Nineteenth holes H19 spaced apart from each other in the first direction DR1 and extending in the second direction DR2 may be defined in the cam CAM3_1. Twentieth holes H20 extending in the second direction DR2 may be defined in the first spring units SPU1. Twenty first holes H21 spaced apart from each other in the first direction DR1 and extending in the second direction DR2 may be defined in the cam CAM3_2. Twenty second holes H22 spaced apart from each other in the first direction DR1 may be defined in the cam CAM4_2. Substantially, the twenty second holes H22 may be fastening portions.

The opposite side of the fourth gear part GR4 may pass through corresponding holes among the nineteenth holes H19 defined in the cam CAM3_1, the twentieth holes H20 defined in the first spring unit SPU1, and the twenty first holes H21 defined in the cam CAM3_2. The opposite side of the fourth gear part GR4 passing through the holes may be coupled to the twenty second hole H22 defined in the cam CAM4_2.

Main pins MPN may be spaced apart from each other in the first direction DR1 and may extend in the second direction DR2. A hook groove MPG may be defined on a side of the main pin MPN that faces the main frame MFM.

Twenty third holes H23 spaced apart from each other in the first direction DR1 and extending in the second direction DR2 may be defined in the cam CAM4_1. Twenty fourth holes H24 spaced apart from each other in the first direction DR1 and extending in the second direction DR2 may be defined in the cam CAM3_1. The nineteenth holes H19 may be defined between the twenty fourth holes H24. Twenty fifth holes H25 spaced apart from each other in the first direction DR1 and extending in the second direction DR2 may be defined in the second spring units SPU2. The twentieth holes H20 may be defined between the twenty fifth holes H25. Twenty sixth holes H26 may be defined in the cam CAM3_2. The twenty first holes H21 may be disposed between the twenty sixth holes H26. Twenty seventh holes H27 may be defined in the cam CAM4_2. The twenty second holes H22 may be disposed between the twenty seventh holes H27. Substantially, the twenty seventh holes H27 may be fastening portions.

Each of the main pins MPN may pass through corresponding holes among the twenty third holes H23, the twenty fourth holes H24, the twenty fifth holes H25, the twenty sixth holes H26, and the twenty seventh holes H27 and may be connected to the third unit UN3. Each of the hook grooves MPG of the main pins MPN may be connected to a corresponding hook portion MPF among hook portions MPF defined in the third unit UN3.

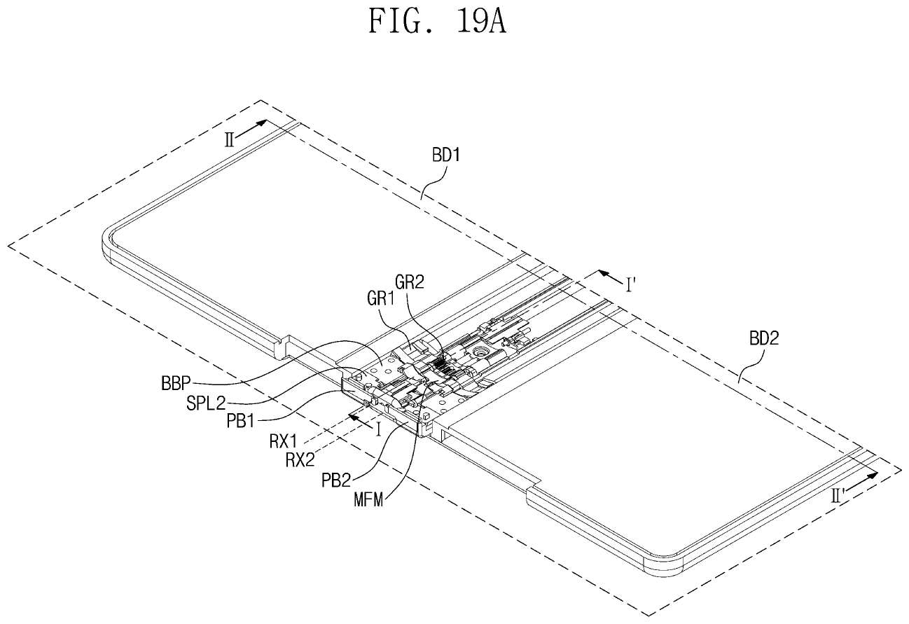

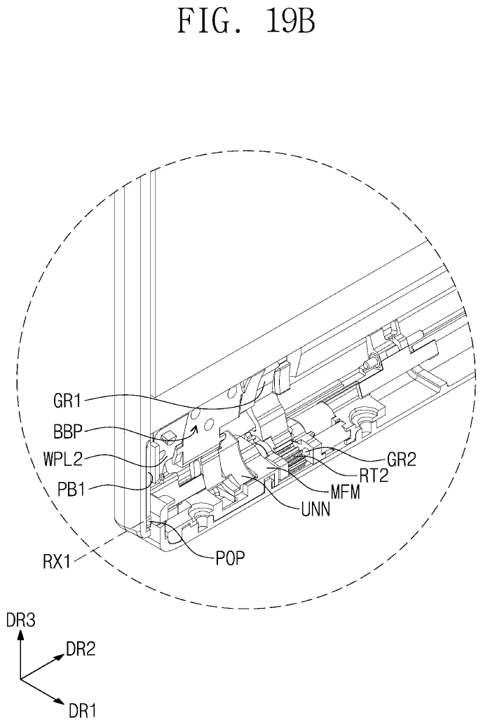

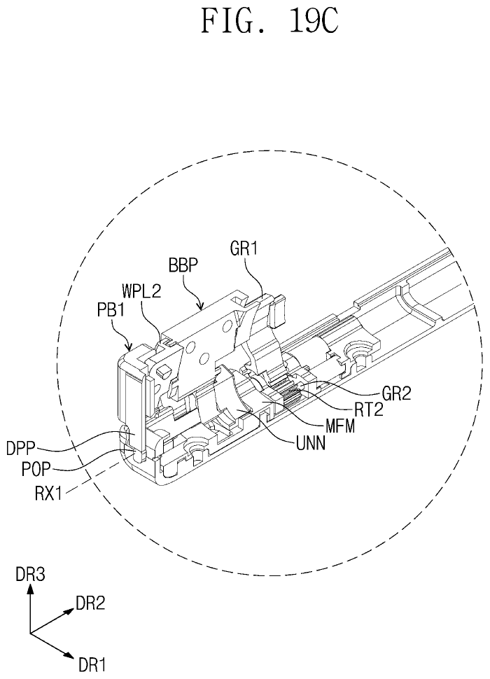

FIGS. 19A to 19C are schematic views illustrating the first hinge part and the brackets of FIG. 12.

For example, FIG. 19A is a perspective view illustrating any one of the first hinge parts HS1. FIG. 19B is a sectional view taken along line I-I′ of FIG. 19A. FIG. 19C is a sectional view of the first hinge part HS1 and the first bracket PB1 separated from the first body BD1.

To describe the positions of the first and second brackets PB1 and PB2 and the protrusions POP in an unfolded state, a portion of the first body BD1 and a portion of the second body BD2 adjacent to the first hinge part HS1 are omitted.

Hereinafter, for convenience of description, any one of the first hinge parts HS1 opposite each other in the second direction DR2 will be described. Furthermore, for convenience of description, the wing plates WPT are omitted in FIGS. 19A to 19C.

Reference will be made to the drawings of FIGS. 14A to 14C for description as needed.

Referring to FIGS. 14A and 19A, the first gear parts GR1 and the sub-frames BBP may be connected to each other. The sub-frames BBP may be connected with the first bracket PB1 and the second bracket PB2 by the second connecting parts WPL2. The sub-frames BBP may be connected with the first bracket PB1 and the second bracket PB2 through screws (not illustrated). Although not illustrated, the sub-frames BBP may be connected with the wing plates WPT by the second connecting parts WPL2.

Referring to FIGS. 14A, 19A and 19B, in case that the first protrusions RPT1 of the first gear parts GR1 and the second protrusions RPT2 of the second gear parts GR2 are engaged with each other to rotate, the sub-frames BBP connected to the first gear parts GR1 may be rotated about the biaxial rotational axes RX1 and RX2. In case that the sub-frames BBP are rotated, the first sliding protrusions SLO1 may move along curved paths defined by the first sliding grooves S G1.

In case that the sub-frames BBP are rotated about the biaxial rotational axes RX1 and RX2, the first body BD1 and the second body BD2 connected to the sub-frames BBP may be rotated about the biaxial rotational axes RX1 and RX2.

In case that the sub-frames BBP are rotated about the biaxial rotational axes RX1 and RX2, the first bracket PB1 and the second bracket PB2 connected to the sub-frames BBP may be rotated about the biaxial rotational axes RX1 and RX2.

Although not illustrated, the wing plates WPT connected to the sub-frames BBP may be rotated about the biaxial rotational axes RX1 and RX2 in case that the sub-frames BBP are rotated about the biaxial rotational axes RX1 and RX2.

Referring to FIGS. 19B and 19C, only the first bracket PB1 and one protrusion POP are illustrated in FIGS. 19B and 19C. However, the second bracket PB2 and another protrusion POP opposite each other in the second direction DR2 may also be substantially identically disposed. Hereinafter, a coupling relationship between one first bracket PB1 and one protrusion POP will be described.

In case that the first bracket PB1 rotates, the protrusion POP may be fixed without being rotated. A side of the first bracket PB1 may move along an outer surface of a corresponding one of the protrusions POP. A side of the flat protruding portion DPP of the first bracket PB1 may move along an outer surface of a corresponding one of the protrusions POP.

One of opposite sides of the first bracket PB1 opposite each other in the third direction DR3 may make contact with the corresponding protrusion POP. As illustrated in FIG. 19B, an opposite side of the first bracket PB1 in the third direction DR3 may be brought into contact with the first body BD1. Accordingly, the protrusion POP may be fixed to the exposure recesses OEG by the first bracket PB1.

In case that an external impact is applied to the hinge module HGM in a case in which the protrusions POP and the brackets PB1 and PB2 do not exist in the hinge module HGM of the display device DD, the first hinge parts HS1 and the second hinge part HS2 may be separated from the hinge cover HBC, and the hinge module may be damaged or pushed. Therefore, the display module DM may be damaged.

Movement of the protrusions POP protruding from the first hinge parts HS1 may be restricted by the first bracket PB1 and the second bracket PB2 during folding or unfolding. A side of the first bracket PB1 and a side of the second bracket PB2 may make contact with the protrusions POP, and an opposite side of the first bracket PB1 and an opposite side of the second bracket PB2 may make contact with the first and second bodies BD1 and BD2. Accordingly, movement of the protrusions POP may be restricted. For example, even though a drop impact is applied to the hinge module HGM in a direction parallel to the direction of being pushed in, the first and second brackets PB1 and PB2 may be brought into contact with the protrusions POP protruding from the main frame MFM and may fix the protrusions POP, and thus the first and second brackets PB1 and PB2 may prevent separation of the protrusions POP from the exposure recesses OEG. Accordingly, a risk of damage caused by movement of the hinge module HGM may be reduced.

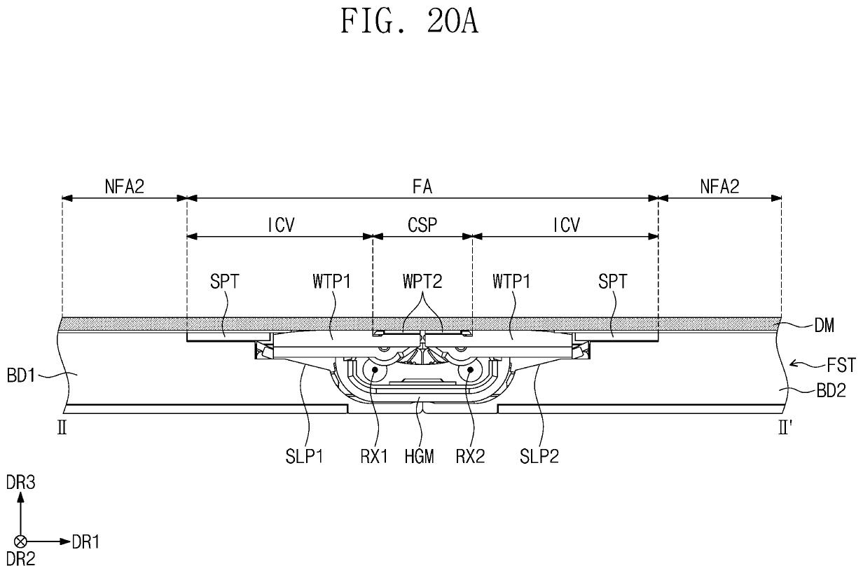

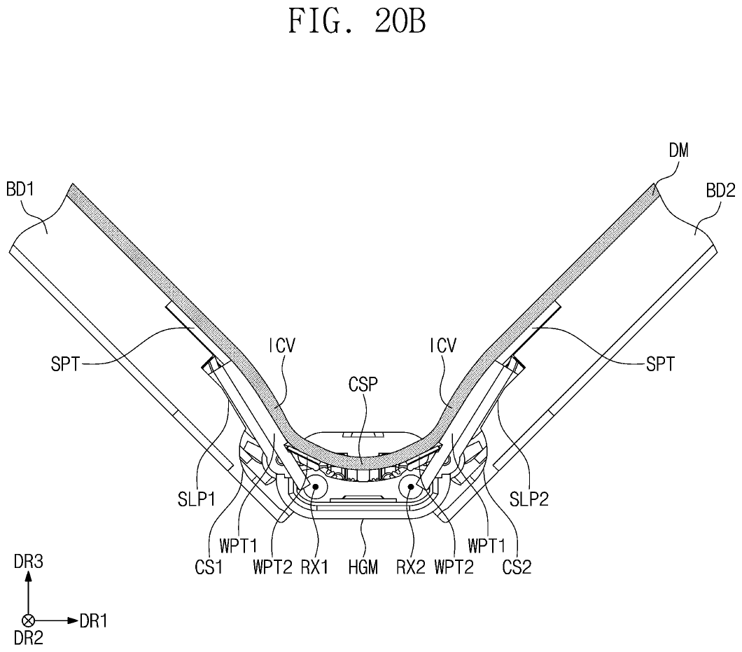

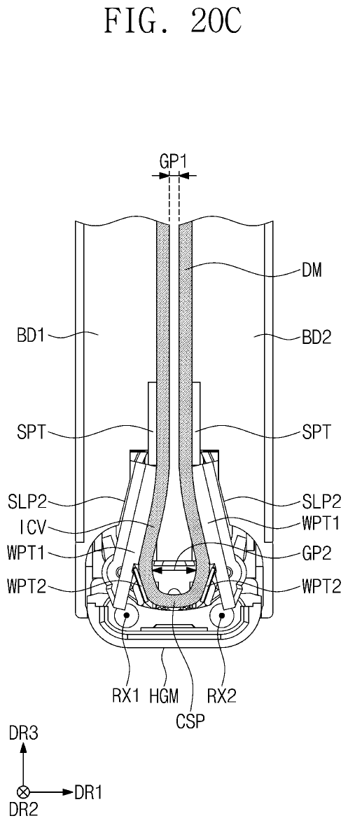

FIG. 20A is a schematic sectional view taken along line II-IF of FIG. 19A.

FIGS. 20B and 20C are schematic views for describing a folded state of the folding set and the display module illustrated in FIG. 20A.

Referring to FIG. 20A, the display module DM may be disposed on the folding set FST. The folding region FA may include a curved portion CSP and reverse curvature portions ICV. The reverse curvature portions ICV may be disposed between the curved portion CSP and the first non-folding region NFA1 and between the curved portion CSP and the second non-folding region NFA2.

The first body BD1 may be disposed under the first non-folding region NFA1, and the second body BD2 may be disposed under the second non-folding region NFA2. The first and second rotational axes RX1 and RX2 may overlap the folding region FA in plan view. The first rotational axis RX1 and the second rotational axis RX2 may be disposed below the upper surface of the display module DM.

The upper surfaces of the first and second bodies BD1 and BD2 facing the reverse curvature portions ICV may be defined as the first inclined surface SLP1 and the second inclined surface SLP2. The upper surface of the first body BD1 overlapping the first wing plate WPT1 disposed on the left side may be formed to be the first inclined surface SLP1. The upper surface of the second body BD2 overlapping the first wing plate WPT1 disposed on the right side may be formed to be the second inclined surface SLP2. The first inclined surface SLP1 and the second inclined surface SLP2 may be disposed to have a step with the upper surfaces of the first and second bodies BD1 and BD2 disposed under the first and second non-folding regions NFA1 and NFA2.

The wing plates WPT may be disposed between the hinge module HGM and the folding region FA. The first wing plates WPT1 may be disposed between the first and second inclined surface SLP1 and SLP2 and the reverse curvature portions ICV. The first wing plates WPT1 may be adjacent to the stepped portions.

Referring to FIGS. 20B and 20C, the folding set FST may be folded about the first and second rotational axes RX1 and RX2, and thus the display module DM may be folded. The folding region FA may be bent, and the display module DM may be folded. The display module DM may rotate about the biaxial rotational axes and may be folded such that the first non-folding region NFA1 and the second non-folding region NFA2 face each other.

The curved portion CSP may be bent in a curved shape in case that the display module DM is folded. The curved portion CSP may be bent to have a predetermined or selected curvature. The reverse curvature portions ICV may be bent opposite to the curved portion CSP. The reverse curvature portions ICV may be bent to be symmetrical to each other. The curvatures of the reverse curvature portions ICV may differ from the curvature of the curved portion CSP.

Depending on the above-described folding structure, the first gap GP1 between the first non-folding region NFA1 and the second non-folding region NFA2 may be smaller than the second gap GP2 between the boundaries defined between the curved portion CSP and the reverse curvature portions ICV in case that the display module DM is folded. Accordingly, in case that the display module DM is folded, the display module DM may be folded in a dumbbell shape.

In case that the folding region FA is in an unfolded state, the wing plates WPT may be arranged in the first direction DR1 and may support the folding region FA. In case that the folding region FA is folded, the first wing plates WPT1 and the second wing plates WPT2 may rotate and may be disposed along the folding region FA. The wing plates WPT may be arranged in a dumbbell shape like the folding region FA.

In case that the display module DM is folded, the first wing plates WPT1 may move toward and make contact with the first inclined surface SLP1 and the second inclined surface SLP2 depending on stress of the folding region FA. The second wing plates WPT2 may be disposed to surround the lower surface of the folding region FA that faces the wing plates WPT.

According to embodiments of the disclosure, in case that an impact force is applied to the hinge module, the brackets may limit movement of the protrusions connected to the hinge module. Accordingly, movement of the hinge module connected to the protrusions may be limited. Thus, a risk of damage caused by the movement of the hinge module may be reduced even though a drop impact is applied.

While the disclosure has been described with reference to embodiments thereof, it will be apparent to those of ordinary skill in the art that various changes and modifications may be made thereto without departing from the spirit and scope of the disclosure.

What is claimed is:

1. A display device comprising:
a display assembly including a first non-folding region and a second non-folding region that are disposed in a first direction and a folding region disposed between the first and second non-folding regions;
a first body disposed under the first non-folding region;
a second body disposed under the second non-folding region;
a hinge assembly disposed between the first body and the second body and defining biaxial rotational axes extending parallel to a second direction intersecting the first direction;
a first bracket and a second bracket that are disposed on opposite sides of the hinge assembly opposite each other in the second direction, the first bracket and the second bracket being disposed in the first direction and adjacent to the biaxial rotational axes; and
a plurality of protrusions connected to the opposite sides of the hinge assembly and protruding between the first bracket and the second bracket.

2. The display device of claim 1, wherein in case that the display assembly is unfolded, the protrusions make physical contact with a side of the first bracket and a side of the second bracket facing each other in the first direction.

3. The display device of claim 2, wherein the protrusions are disposed between the biaxial rotational axes when viewed in the second direction.

4. The display device of claim 2, wherein
in case that the display assembly is folded, the first and second bodies rotate about the biaxial rotational axes and face each other, and
the protrusions make physical contact with the side of the first bracket and the side of the second bracket in a third direction intersecting a plane defined by the first and second directions.

5. The display device of claim 4, wherein
the protrusions are fixed without being rotated, and
the side of the first bracket and the side of the second bracket move along outer surfaces of the protrusions when viewed in the second direction.

6. The display device of claim 4, wherein the protrusions are supported by the first and second brackets and limit movement of the hinge assembly.

7. The display device of claim 1, wherein
the hinge assembly includes first hinge parts spaced apart from each other in the second direction and defining the opposite sides of the hinge assembly, and
the first bracket and the second bracket are connected to a corresponding first hinge part among the first hinge parts.

8. The display device of claim 7, wherein the first bracket and the second bracket are connected to the outside of the corresponding first hinge part among the outsides of the first hinge parts not facing each other in the second direction and rotate about the biaxial rotational axes.

9. The display device of claim 7, wherein
each of the first hinge parts includes:
a main frame;
a plurality of sub-frames connected to opposite sides of the main frame opposite each other in the second direction; and
a plurality of first gear parts overlapping the biaxial rotational axes and rotate about the biaxial rotational axes in opposite directions, and
the protrusions protrude from a side of the main frame facing toward the outside of the hinge assembly in the second direction, and the first gear parts are connected to an opposite side of the main frame opposite the side of the main frame in the second direction.

10. The display device of claim 9, wherein
the sub-frames are coupled to the first gear parts, and
in case that the first gear parts rotate, the sub-frames rotate together with the first gear parts.

11. The display device of claim 10, wherein
the first bracket and the second bracket are connected to the sub-frames of the corresponding first hinge part, and
in case that the first gear parts rotate, the first bracket and the second bracket rotate about the biaxial rotational axes.

12. The display device of claim 10, wherein each of the first hinge parts further includes:
a plurality of second gear parts disposed between the first gear parts and engaged with the first gear parts to rotate together with the first gear parts; and
a plurality of coupling pieces connecting the sub-frames to the main frame.

13. The display device of claim 12, wherein
the sub-frames are disposed in sliding grooves defined on surfaces of the coupling pieces facing toward the outside of the hinge assembly, and
the sliding grooves have a curved shape, and in case that the first gear parts rotate, the sub-frames move along a curved path defined by the sliding grooves.

14. The display device of claim 9, further comprising:
a plurality of wing plates disposed on the first body and the second body and connected to opposite sides of the first hinge parts opposite each other in the first direction.

15. The display device of claim 14, wherein
each of the wing plates includes:
a first wing plate; and
a second wing plate closer to the centers of the first hinge parts than the first wing plate, the second wing plate being rotatably coupled to the first wing plate, and
the second wing plate is connected to a side of the first wing plate facing the second wing plate.

16. The display device of claim 15, wherein the first and second wing plates of the wing plates are coupled to the sub-frames and rotate together with the sub-frames.

17. The display device of claim 15, wherein the first wing plates of the wing plates are coupled to the first gear parts and rotate together with the first gear parts.

18. The display device of claim 1, wherein the folding region includes:
a curved portion bent in a curved shape; and
reverse curvature portions disposed between the first non-folding region and the curved portion and between the second non-folding region and the curved portion and bent so as to be symmetrical to each other, the reverse curvature portions being bent opposite to the curved portion.

19. A display device comprising:
a display assembly including a first non-folding region, a folding region, and a second non-folding region disposed in a first direction;
a first body disposed under the first non-folding region;
a second body disposed under the second non-folding region;
a hinge assembly disposed between the first body and the second body and defining biaxial rotational axes extending parallel to a second direction intersecting the first direction; and
a plurality of protrusions connected to the opposite sides of the hinge assembly opposite each other in the second direction and protruding outside the hinge assembly.

20. A display device comprising:
a display assembly including a first non-folding region and a second non-folding region disposed in a first direction and a folding region disposed between the first and second non-folding regions;
a first body disposed under the first non-folding region;
a second body disposed under the second non-folding region;
a hinge assembly disposed between the first body and the second body and defining biaxial rotational axes extending parallel to a second direction intersecting the first direction;
a first bracket and a second bracket that are disposed on opposite sides of the hinge assembly opposite each other in the second direction, the first bracket and the second bracket being disposed in the first direction and adjacent to the biaxial rotational axes; and
a plurality of protrusions protruding between the first bracket and the second bracket from the opposite sides of the hinge assembly and that physically contact a side of the first bracket and a side of the second bracket facing each other.
